(19) United States
(12) Patent Application Publication
(10) Pub. No.: US 2025/0357221 A1
(43) Pub. Date: Nov. 20, 2025

(54) DISPLAY PANEL, DISPLAY DEVICE, AND PREPARATION METHOD AND USE METHOD THEREOF

(71) Applicant: Xiamen Tianma Optoelectronics Co., Ltd., Xiamen (CN)

(72) Inventors: Qiaoning ZHENG, Xiamen (CN); Wenjing ZHU, Xiamen (CN); Xin ZHANG, Xiamen (CN)

(73) Assignee: Xiamen Tianma Optoelectronics Co., Ltd., Xiamen (CN)

(21) Appl. No.: 18/783,402

(22) Filed: Jul. 24, 2024

(30) Foreign Application Priority Data
May 16, 2024 (CN) 202410608741.1

(51) Int. Cl. H01L 21/66; H01L 27/12

(52) U.S. Cl. CPC H01L 22/32; H01L 22/14; H10D 86/021; H10D 86/441; H10D 86/60

(57) ABSTRACT

Embodiments of the present disclosure provide a display panel, a display device, a preparation method and a use method thereof, where the display panel includes a display area and a border area that surrounds the display area; in which the display area includes a data signal line; and the border area includes a test signal line and a common voltage signal line, which extend around the display area; and the test signal line is configured so that: in a test stage of the display panel, the test signal line is electrically connected to the data signal line and is input with a test signal; and in a use stage of the display panel, the test signal line is electrically connected to the common voltage signal line and is input with a first common voltage signal or outputs a second common voltage signal on the common voltage signal line.

### CROSS-REFERENCE TO RELATED APPLICATIONS

This application claims priority to Chinese Patent Application No. 202410608741.1, titled “DISPLAY PANEL, DISPLAY DEVICE, AND PREPARATION METHOD AND USE METHOD THEREOF” and filed on May 16, 2024, which is hereby incorporated by reference in its entirety.

### TECHNICAL FIELD

The present application relates to the field of display technology, and in particular, to a display panel, a display device, and a preparation method and a use method thereof.

### BACKGROUND

With the continuous development of display technology, consumers' requirements for display panels are constantly increasing. Various types of displays have emerged and developed rapidly, such as liquid crystal display panels, organic light-emitting display panels, etc. Various signal lines need to be laid in the border areas of these display panels, such as test signal lines, common voltage signal lines, control signal lines, etc. The quantity of these signal lines is large and the signal lines occupy a certain space, resulting in a relatively large border area of the display panel, which is not conducive to achieving a narrow border design of the display panel.

### SUMMARY

The embodiments of the present disclosure provide a display panel, a display device, and a preparation method and a use method thereof, so as to improve the situation that the test signal line is useless and idle after the visual test (Visual Test, VT), improve the utilization rate of the test signal line during the use stage, and help reduce the border of the display panel and realize the narrow border design of the display panel.

In a first aspect, the embodiments of the present disclosure provide a display panel including a display area and a border area that surrounds the display area, where
the display area includes a data signal line, and the border area includes a test signal line and a common voltage signal line, which extend around the display area; and
the test signal line is configured to:
be electrically connected to the data signal line and be input with a test signal during a test stage of the display panel; and
be electrically connected to the common voltage signal line and be input with a first common voltage signal or output a second common voltage signal on the common voltage signal line during a use stage of the display panel.

In a second aspect, an embodiment of the present disclosure further provides a method for preparing a display panel, including:
preparing the display panel including a display area and a border area that surrounds the display area, the display area including a data signal line, and the border area including a test signal line and a common voltage signal line, which extend around the display area;
electrically connecting the test signal line with the data signal line, and inputting a test signal into the test signal line to test the display panel;
electrically connecting the test signal line with the common voltage signal line.

In a third aspect, an embodiment of the present disclosure further provides a method for using a display panel including a display area and a border area that surrounds the display area, the display area including a data signal line, and the border area including a test signal line and a common voltage signal line, and the test signal line and the common voltage signal line extending around the display area;
the method for using the display panel including:
controlling the test signal line to be electrically connected to the data signal line, and inputting a test signal into the test signal line during a test stage of the display panel;
controlling the test signal line to be electrically connected to the common voltage signal line, and inputting a first common voltage signal into the test signal line or outputting a second common voltage signal on the common voltage signal line through the test signal line during a use stage of the display panel.

In a fourth aspect, an embodiment of the present disclosure further provides a display device, including a display panel as described in any one of the first aspects.

The embodiments of the present disclosure provide a display panel, a display device, and a preparation method and a use method thereof. The display panel includes a display area and a border area that surrounds the display area; the display area includes a data signal line; the border area includes a test signal line and a common voltage signal line, and the test signal line and the common voltage signal line extend around the display area; the test signal line is configured so that: during a test stage of the display panel, the test signal line is electrically connected to the data signal line and is input with a test signal; during a use stage of the display panel, the test signal line is electrically connected to the common voltage signal line and is input with a first common voltage signal or outputs a second common voltage signal on the common voltage signal line. In the display panel, the electrical connection relationships of the test signal line with the data signal line and the common voltage signal line are reasonably set. Thereby, in the test stage of the display panel, the test signal is input into the test signal line and transmitted to the data signal line, so as to realize the VT test of the display panel; in the use stage of the display panel, the common voltage signal can be input into the test signal line or the test signal line can output the common voltage signal and balance the voltage drop of the common voltage signal line in the extension direction. In this way, the test signal line can be used in both the test stage and the use stage, which improves the situation that the test signal line is useless and idle after the VT test, improves the utilization rate of the test signal line with no need to arrange an additional detection signal line to monitor the voltage fluctuation on the common voltage signal line, improves the uniformity and stability of the common voltage signal line, and can effectively reduce the space for the border area of the display panel to facilitate realization of the narrow border design of the display panel. In addition, when the space for the border area of the display panel is fixed, more other circuit structures can be arranged in the border area, which improves the flexibility of the circuit design of the border area and thus allows to provide more drive signals and test signals for the display panel, thereby facilitating improvement of the performance of the display panel.

### BRIEF DESCRIPTION OF THE DRAWINGS

FIG. 1 is a schematic structural diagram of a display panel in the related art;

FIG. 2 is a schematic structural diagram of a display panel provided by an embodiment of the present disclosure;

FIG. 3 and FIG. 4 are schematic structural diagrams of two other display panels provided by an embodiment of the present disclosure;

FIG. 5 is a schematic structural diagram of another display panel provided by an embodiment of the present disclosure;

FIG. 6 is a schematic structural diagram of another display panel provided by an embodiment of the present disclosure;

FIG. 7 is a schematic structural diagram of another display panel provided by an embodiment of the present disclosure;

FIG. 8 is a schematic structural diagram of another display panel provided by an embodiment of the present disclosure;

FIG. 9 is a schematic structural diagram of another display panel provided by an embodiment of the present disclosure;

FIG. 10 is a time sequence diagram of a first control signal line and a second control signal line of the display panel shown in FIG. 9;

FIG. 11 is a schematic structural diagram of another display panel provided by an embodiment of the present disclosure;

FIG. 12 is a time sequence diagram of the first control signal line and the second control signal line of the display panel shown in FIG. 11;

FIG. 13 is a schematic structural diagram of another display panel provided by an embodiment of the present disclosure;

FIG. 14 is a time sequence diagram of the first control signal line and the second control signal line of the display panel shown in FIG. 13;

FIG. 15 is a schematic structural diagram of a top view of a display panel in a test stage provided by an embodiment of the present disclosure;

FIG. 16 is a schematic diagram of a cross-section in the MM′ direction of the display panel in the test stage shown in FIG. 15;

FIG. 17 is a schematic structural diagram of a top view of a display panel in a use stage provided by an embodiment of the present disclosure;

FIG. 18 is a schematic diagram of a cross-section in the NN′ direction of the display panel in the use stage shown in FIG. 17;

FIG. 19 is a schematic structural diagram of a top view of another display panel in the test stage provided by an embodiment of the present disclosure;

FIG. 20 is a schematic diagram of a cross-section in the PP′ direction of the display panel in the test stage shown in FIG. 19;

FIG. 21 is a schematic structural diagram of a top view of another display panel in the use stage provided by an embodiment of the present disclosure;

FIG. 22 is a schematic diagram of a cross-section in the QQ′ direction of the display panel in the use stage shown in FIG. 21;

FIG. 23 is a schematic structural diagram of a top view of another display panel in the test stage provided by an embodiment of the present disclosure;

FIG. 24 is a schematic diagram of a cross-section in the EE′ direction of the display panel in the test stage shown in FIG. 23;

FIG. 25 is a schematic structural diagram of a top view of another display panel in the use stage provided by an embodiment of the present disclosure;

FIG. 26 is a schematic diagram of a cross-section in the FF′ direction of the display panel in the test stage shown in FIG. 25;

FIG. 27 is a schematic structural diagram of another display panel provided by an embodiment of the present disclosure;

FIG. 28 to FIG. 31 are schematic structural diagrams of four further display panels provided by embodiments of the present disclosure;

FIG. 32 is a schematic structural diagram of another display panel provided by an embodiment of the present disclosure;

FIG. 33 is a flowchart of a method for preparing a display panel provided by an embodiment of the present disclosure;

FIG. 34 is a flowchart of another method for preparing the display panel provided by an embodiment of the present disclosure;

FIG. 35 is a flowchart of a method for using the display panel provided by an embodiment of the present disclosure;

FIG. 36 is a flowchart of another method for preparing the display panel provided by an embodiment of the present disclosure;

FIG. 37 is a flowchart of another method for preparing the display panel provided by an embodiment of the present disclosure; and

FIG. 38 is a schematic structural diagram of a display device provided by an embodiment of the present disclosure.

### DETAILED DESCRIPTION

The present disclosure is further described in detail below in conjunction with the drawings and embodiments. It is understood that the specific embodiments described herein are only used to explain the present disclosure, but not to limit the present disclosure. It should also be noted that, for the convenience of description, the drawings only show relevant parts rather than all structures.

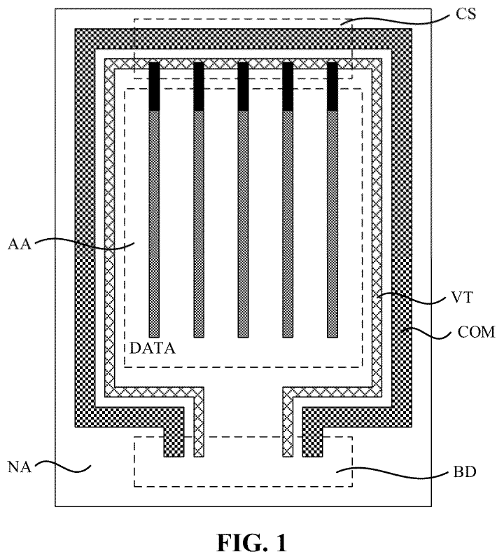

FIG. 1 is a schematic structural diagram of a display panel in the related art. As shown in FIG. 1, the display panel includes a display area AA and a border area NA that surrounds the display area AA. The border area NA includes a binding area BD and a test area CS, which are located on two sides of the display area AA that are away from each other, respectively. Exemplarily, in one embodiment, the binding area BD can be located in a lower border area of the display panel, and the test area CS can be located in an upper border area of the display panel. The display area AA includes a data signal line DATA, and the border area NA includes a test signal line VT and a common voltage signal line COM, both extending from the binding area BD to the test area CS, and extending in parallel with edges of the display area AA at a periphery of the display area AA; the test signal line VT and the common voltage signal line COM are insulated from each other and have no electrical connection relationship.

On the one hand, during the process of the display panel leaving the factory, a VT test is generally performed, that is, the test signal line VT in the test area CS is electrically connected to the data signal line DATA in the display area AA, so that a test signal is input through the test signal line VT and transmitted to the data signal line DATA. The data signal line DATA can transmit the test signal to the sub-pixels of multiple colors in the display area AA each, so as to realize the display/lighting test of the sub-pixels in the display area AA. Exemplarily, black filled areas in FIG. 1 are shown as an electrical connection relationship between the test signal line VT and the data signal line DATA. The VT test helps to detect the defects of the sub-pixels in the display area AA, and then repair the sub-pixels according to the defective conditions, thereby effectively improving the product yield of the display panel, and avoiding the factory delivery of defective products. Exemplarily, the test signal input by the test signal line VT can be written to the pixel circuit of the red sub-pixel through the data signal line DATA, so that the normal red sub-pixel can be lit. If there is a red sub-pixel that is not lit in the display area AA, it proves that the red sub-pixel that is not lit is defective. Similarly, the tests of the green sub-pixel and the blue sub-pixel are the same. However, after the test of sub-pixels of all colors in the display area AA is completed, these test signal lines VT are completely useless. These test signal lines VT also occupy a large amount of border space in the border area NA, which is not conducive to realizing a narrow border design of the display panel.

On the other hand, the common voltage signal line COM extends from the binding area BD of the lower border to the test area CS of the upper border. The voltage drop on the common voltage signal line COM is large, and the voltage on the common voltage signal line COM is difficult to accurately evaluate in real time, and thus the uniformity and stability in the panel cannot be guaranteed. Exemplarily, a detection signal line can be arranged at the left border area and/or the right border area of the display panel, and the detection signal line can monitor and compensate for the fluctuation of the voltage on the common voltage signal line COM. However, the arrangement of the detection signal line may also occupy the border space for the border area NA, which is not conducive to realizing the narrow border design of the display panel. In addition, in order to effectively improve the uniformity and stability in the panel, if the border space for the border area NA allows, the line width of the common voltage signal line COM can also be set as wide as possible to balance the voltage drop of the common voltage signal line COM in an extension direction. However, with the increase of the line width of the common voltage signal line COM, the narrow border design of the display panel cannot be realized. This is especially reflected in the upper border area of the display panel, which includes both the test signal line VT for VT testing of the display panel and the common voltage signal line COM for improving the uniformity and stability in the panel, resulting in a tight space in the upper border area of the display panel.

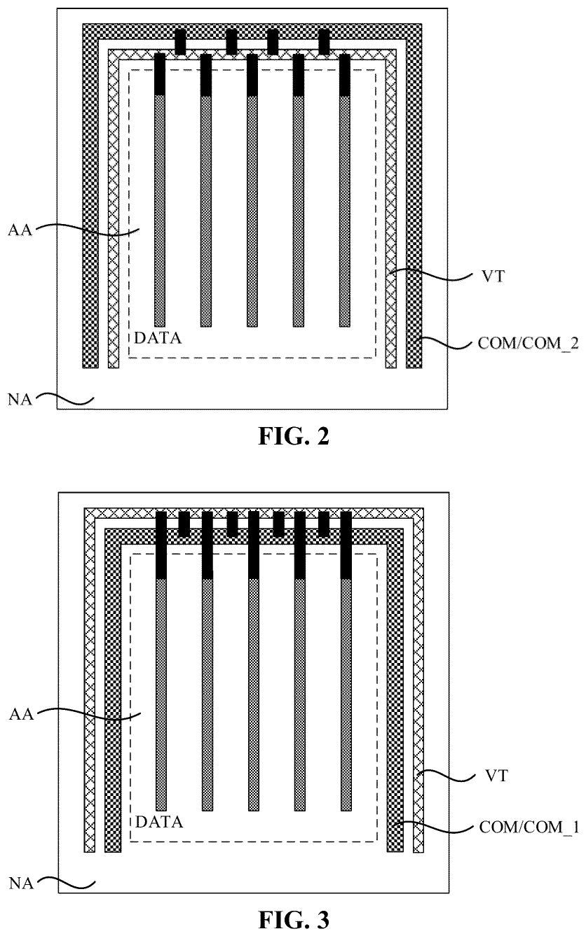

In view of the above-mentioned technical problems, embodiments of the present disclosure provide a display panel. FIG. 2 is a schematic structural diagram of a display panel provided by an embodiment of the present disclosure. As shown in FIG. 2, the display panel includes a display area AA and a border area NA that surrounds the display area AA; the display area AA includes a data signal line DATA; the border area NA includes a test signal line VT and a common voltage signal line COM, which extend around the display area AA; the test signal line VT is configured so that: during a test stage of the display panel, the test signal line VT is electrically connected to the data signal line DATA and is input with a test signal; during a use stage of the display panel, the test signal line VT is electrically connected to the common voltage signal line COM and is input with a first common voltage signal or outputs a second common voltage signal on the common voltage signal line COM.

Specifically, the display panel includes a display area AA and a border area NA that surrounds the display area AA. The display area AA includes a data signal line DATA, and the border area NA includes a test signal line VT and a common voltage signal line COM which extend around the display area AA. In this embodiment, the electrical connection relationships of the test signal line VT with the data signal line DATA and the common voltage signal line COM can be reasonably set, so that the test signal line VT can be applied to not only the test stage of the display panel but also the use stage of the display panel. That is, in the test stage of the display panel, the test signal line VT can be electrically connected to the data signal line DATA, and a test signal can be input to the test signal line VT and then transmitted to the data signal line DATA. The data signal line DATA can transmit the test signal to sub-pixels of multiple colors in the display area AA, so as to realize the display/lighting test of the sub-pixels in the display area AA.

And in the use stage of the display panel, the test signal line VT can be electrically connected to the common voltage signal line COM, and the first common voltage signal is input to the test signal line VT. Exemplarily, the test signal line VT can play a role in compensating the voltage drop of the voltage on the common voltage signal line COM, so as to balance the voltage drop magnitudes of the voltages on the common voltage signal line COM at different extension positions, thereby improving the uniformity and stability in the panel. Exemplarily, the first common voltage signal can change in real time according to the fluctuation of the voltage on the common voltage signal line COM and be input to the test signal line VT. Or, in the use stage of the display panel, the test signal line VT can be electrically connected to the common voltage signal line COM, and the second common voltage signal on the common voltage signal line COM can be output through the test signal line VT. Exemplarily, the test signal line VT can play a role in detecting the fluctuation of the voltage on the common voltage signal line COM, so as to obtain the voltage magnitudes of the common voltage signal line COM at different extension positions, facilitating the subsequent feedback adjustment of the voltage magnitude input to the common voltage signal line COM. Exemplarily, the second common voltage signal can obtain the voltage on the common voltage signal line COM in real time according to the in-panel refresh frequency and output the voltage. In this way, during the test stage and the use stage of the display panel, the electrical connection relationships of the test signal line VT with the data signal line DATA and the common voltage signal line COM are adjusted, and a new design scheme for the test signal line VT is realized such that in the different stages of the display panel, the test signal line VT plays different roles correspondingly. Exemplarily, black filled areas in FIG. 2 are shown as an electrical connection relationship between the test signal line VT and the data signal line DATA, and an electrical connection relationship between the test signal line VT and the common voltage signal line COM. The embodiment is only for example here but not for the purpose of limitation. The black filled areas in the subsequent figures can be understood likewise.

In addition, it can be understood that, during the use stage of the display panel, the test signal line VT can be electrically connected to the common voltage signal line COM, and the first common voltage signal can be input into the test signal line VT, so that the common voltage signal can be input into the common voltage signal line COM and the test signal line VT. In this way, the test signal line VT can also be regarded as a part of the common voltage signal line COM, and the test signal line VT plays a role in replacing part of the common voltage signal line COM. Exemplarily, the test signal line VT and the common voltage signal line COM extend around the display area AA, and the electrical connection between the test signal line VT and the common voltage signal line COM can also be understood as the test signal line VT and the common voltage signal line COM being connected in parallel. This can also further reduce the impedance of the common voltage signal line COM, which is conducive to improving the stability of the common voltage signal transmitted on the common voltage signal line COM.

In a specific embodiment, when the test signal line VT is regarded as a part of the common voltage signal line COM, in order to ensure the uniformity and stability in the panel, it is not necessary to increase the line width of the common voltage signal line COM, but it can be achieved by inputting the first common voltage signal into the test signal line VT for voltage drop compensation or outputting the second common voltage signal for voltage detection, that is, at this time, the line width of the common voltage signal line COM can be further reduced, thereby further reducing the space for the border area NA of the display panel, which is conducive to achieving a design effect of a narrower border.

According to the technical solution in the embodiment of the present disclosure, the display panel includes a display area and a border area that surrounds the display area; the display area includes a data signal line; the border area includes a test signal line and a common voltage signal line, and the test signal line and the common voltage signal line extend around the display area; the test signal line is configured so that: during the test stage of the display panel, the test signal line is electrically connected to the data signal line and is input with the test signal; during the use stage of the display panel, the test signal line is electrically connected to the common voltage signal line and is input with the first common voltage signal or outputs the second common voltage signal on the common voltage signal line. In the display panel, the electrical connection relationships of the test signal line with the data signal line and the common voltage signal line are reasonably set. Thereby, in the test stage of the display panel, the test signal can be input into the test signal line and transmitted to the data signal line, so as to realize the VT test of the display panel; in the use stage of the display panel, the common voltage signal can be input into the test signal line or the test signal line outputs the common voltage signal, so as to balance the voltage drop of the common voltage signal line in the extension direction. In this way, the test signal line can be used in both the test stage and the use stage, which improves the situation that the test signal line is useless and idle after the VT test, improves the utilization rate of the test signal line, with no need to arrange an additional detection signal line to monitor the voltage fluctuation on the common voltage signal line, improves the uniformity and stability of the common voltage signal line, and can effectively reduce the space for the border area of the display panel to facilitate realization of the narrow border design of the display panel. In addition, when the space for the border area of the display panel is fixed, more other circuit structures can be arranged in the border area, which improves the flexibility of the circuit design of the border area and thus allows to provide more driving signals and test signals for the display panel, thereby facilitating improvement of the performance of the display panel.

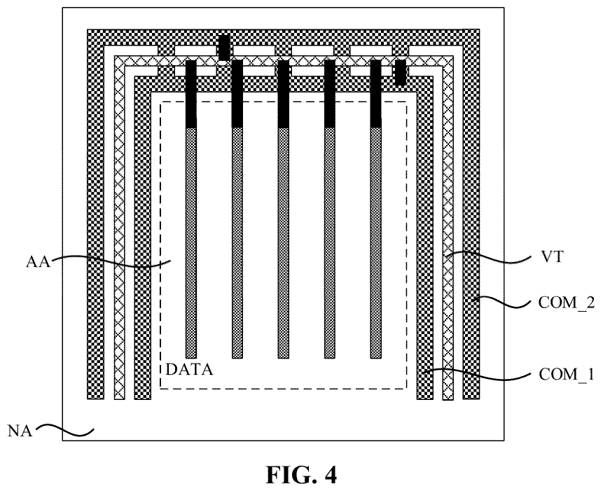

Optionally, FIG. 3 and FIG. 4 are schematic structural diagrams of two other display panels provided by embodiments of the present disclosure. As shown in FIGS. 2, 3 and 4, the common voltage signal line COM includes a first common voltage signal line COM_1 and a second common voltage signal line COM_2, and the first common voltage signal line COM_1 and the second common voltage signal line COM_2 are connected in parallel; the first common voltage signal line COM_1 is located on a side of the test signal line VT close to the display area AA, and the second common voltage signal line COM_2 is located on a side of the test signal line VT away from the display area AA; the test signal line VT is configured to be electrically connected to the first common voltage signal line COM_1 and/or the second common voltage signal line COM_2 during the use stage of the display panel.

Specifically, the common voltage signal line COM includes a first common voltage signal line COM_1 and a second common voltage signal line COM_2, where the first common voltage signal line COM_1 is located on a side of the test signal line VT close to the display area AA, and the second common voltage signal line COM_2 is located on a side of the test signal line VT away from the display area AA. Exemplarily, the first common voltage signal line COM_1 can be understood as an inner common voltage signal line COM, and the second common voltage signal line COM_2 can be understood as an outer common voltage signal line COM. Exemplarily, the arrangement of the first common voltage signal line COM_1 and the second common voltage signal line COM_2 can be determined according to the size of the display panel. Exemplarily, for a small-sized display panel, the overall voltage fluctuation is small, and only a first common voltage signal line COM_1 can be arranged, and there is no need to arrange the second common voltage signal line COM_2. For a large-sized display panel, the overall voltage fluctuation is large, and the transmission voltage drop of the common voltage signal needs to be considered, so a first common voltage signal line COM_1 and a second common voltage signal line COM_2 need to be arranged accordingly. Further, when a first common voltage signal line COM_1 and a second common voltage signal line COM_2 are included in the display panel at the same time, the first common voltage signal line COM_1 and the second common voltage signal line COM_2 can form a parallel structure, and the parallel first common voltage signal line COM_1 and the second common voltage signal line COM_2 can reduce the impedance when transmitting the common signal, thereby effectively improving the problem of common signal attenuation caused by the transmission line impedance, helping to reduce the difference in common signals received by the upper and lower areas of the display area AA, and ensuring the uniformity of the display of the display area AA.

According to the existence of the first common voltage signal line COM_1 and/or the second common voltage signal line COM_2, in the use stage of the display panel, in one embodiment, continuing to refer to FIG. 3, a test signal line VT can be electrically connected to the first common voltage signal line COM_1, and the test signal line VT can compensate or detect the common voltage signal in the first common voltage signal line COM_1. Alternatively, in another embodiment, continuing to refer to FIG. 2, a test signal line VT can be electrically connected to the second common voltage signal line COM_2, and the test signal line VT can compensate or detect the common voltage signal in the second common voltage signal line COM_2. Alternatively, in still another embodiment, continuing to refer to FIG. 4, the test signal line VT may be electrically connected to the first common voltage signal line COM_1 and the second common voltage signal line COM_2 each. The test signal line VT may compensate or detect the common voltage signal in the first common voltage signal line COM_1 and the second common voltage signal line COM_2, and the first common voltage signal line COM_1 and the second common voltage signal line COM_2 may also perform voltage compensation with each other. It is understandable that the first common voltage signal line COM_1 and the second common voltage signal line COM_2 are both used to transmit the common voltage signal to the display area AA, and the functions of the two are exactly the same, and only the positions in the display panel are different.

The following embodiment is drawn by taking the common voltage signal line COM including the second common voltage signal line COM_2 as an example, and the present disclosure is only given as an example and is not intended to be limiting.

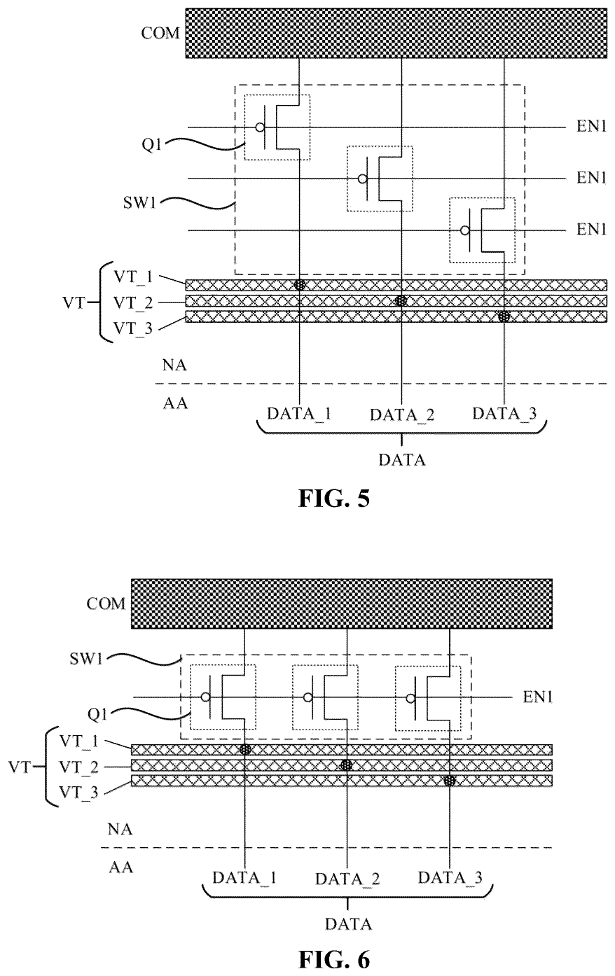

Optionally, FIG. 5 is a schematic structural diagram of another display panel provided by an embodiment of the present disclosure. As shown in FIG. 5, the border area NA further includes a first gating circuit SW1 and a first control signal line EN1; the first gating circuit SW1 is electrically connected to the first control signal line EN1, the test signal line VT and the common voltage signal line COM each; the first control signal line EN1 and the first gating circuit SW1 are configured so that: during the test stage of the display panel, the first control signal line EN1 receives an inactive level signal, and the first gating circuit SW1 controls the test signal line VT and the common voltage signal line COM to be disconnected according to the inactive level signal; during the use stage of the display panel, the first control signal line EN1 receives an active level signal, and the first gating circuit SW1 controls the test signal line VT and the common voltage signal line COM to be connected according to the active level signal.

Specifically, during the test stage of the display panel, the first control signal line EN1 can receive an inactive level signal, and the first control signal line EN1 is electrically connected to the first gating circuit SW1; so the first control signal line EN1 can transmit the inactive level signal to the first gating circuit SW1, and the first gating circuit SW1 may be non-conductive/turned off/form an open circuit according to the inactive level signal. The first gating circuit SW1 is electrically connected to the test signal line VT and the common voltage signal line COM each, so the first gating circuit SW1 can also disconnect the test signal line VT from the common voltage signal line COM, which corresponds to an insulation relationship between the test signal line VT and the common voltage signal line COM. In this way, in the test stage of the display panel, the first gating circuit SW1 is controlled to be turned off, and the test signal line VT can achieve the function of VT testing. The test signal line VT and the common voltage signal line COM have no electrical connection, and the influence of the common voltage signal line COM on the VT test process can also be avoided; in the use stage of the display panel, the first control signal line EN1 can receive an active level signal, and the first control signal line EN1 is electrically connected to the first gating circuit SW1, so the first control signal line EN1 can transmit the active level signal to the first gating circuit SW1, and the first gating circuit SW1 can be turned on/form a closed path according to the active level signal. The first gating circuit SW1 is electrically connected to the test signal line VT and the common voltage signal line COM each, so the first gating circuit SW1 can also establish conductivity between the test signal line VT and the common voltage signal line COM to achieve the electrical connection between the test signal line VT and the common voltage signal line COM. In this way, during the use stage of the display panel, the first gating circuit SW1 is controlled to be turned on, and the test signal line VT can be used for the compensation or detection of the common voltage signal in the common voltage signal line COM. The test signal line VT does not need to be used for VT testing anymore, but the test signal line VT can be regarded as a part of the common voltage signal line COM, thereby avoiding the influence of the test signal line VT on the normal display process.

In addition, it should be noted that the present embodiment is drawn by taking the common voltage signal line COM including the second common voltage signal line COM_2 as an example, and controlling the electrical connection relationship between the test signal line VT and the second common voltage signal line COM_2, which is only for example but not for the purpose of limitation. Exemplarily, the common voltage signal line COM may also include the first common voltage signal line COM_1, and control the electrical connection relationship between the test signal line VT and the first common voltage signal line COM_1.

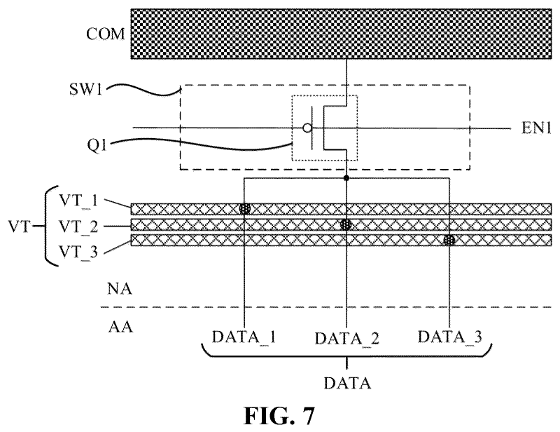

Further, still referring to FIG. 5, the first gating circuit SW1 includes multiple first gating units Q1, each including a first end, a second end and a first control end; the test signal line VT includes a first test signal line VT_1, a second test signal line VT_2 and a third test signal line VT_3; the first test signal line VT_1, the second test signal line VT_2 and the third test signal line VT_3 are electrically connected to the first ends of different first gating units Q1 respectively, and the second ends of the first gating units Q1 are electrically connected to the common voltage signal line COM; the first control ends of different first gating units Q1 are connected to different first control signal lines EN1. FIG. 6 is a schematic structural diagram of another display panel provided by an embodiment of the present disclosure. As shown in FIG. 6, the first gating circuit SW1 includes multiple first gating units Q1, each including a first end, a second end and a first control end; the test signal line VT includes a first test signal line VT_1, a second test signal line VT_2 and a third test signal line VT_3; the first test signal line VT_1, the second test signal line VT_2 and the third test signal line VT_3 are electrically connected to the first ends of different first gating units Q1 respectively, and the second ends of the first gating units Q1 are electrically connected to the common voltage signal line COM; the first control ends of different first gating units Q1 are connected to the same first control signal line EN1. FIG. 7 is a schematic structural diagram of another display panel provided by an embodiment of the present disclosure. As shown in FIG. 7, the first gating circuit SW1 includes a first gating unit Q1 that includes a first end, a second end and a first control end; the test signal line VT includes a first test signal line VT_1, a second test signal line VT_2 and a third test signal line VT_3; the first test signal line VT_1, the second test signal line VT_2 and the third test signal line VT_3 are electrically connected to the first end of the first gating unit Q1, the second end of the first gating unit Q1 is electrically connected to the common voltage signal line COM, and the first control end of the first gating unit Q1 is electrically connected to the first control signal line EN1.

Specifically, the first gating circuit SW1 shown in FIG. 5 includes a plurality of first gating units Q1. Exemplarily, the first gating circuit SW1 may include three first gating units Q1 (from left to right, the first first gating unit Q1, the second first gating unit Q1, and the third first gating unit Q1). Of course, it can be understood that this embodiment is only used to illustrate the quantity setting of the first gating unit Q1, and is not limited. The test signal lines VT include a first test signal line VT_1, a second test signal line VT_2 and a third test signal line VT_3. Exemplarily, the first test signal line VT_1, the second test signal line VT_2 and the third test signal line VT_3 correspond to display/lighting tests of sub-pixels in different columns, respectively.

Exemplarily, in a specific embodiment, the first end of the first first gating unit Q1 is electrically connected to the first test signal line VT_1, the second end of the first first gating unit Q1 is electrically connected to the common voltage signal line COM, and the first control end of the first first gating unit Q1 is electrically connected to the first control signal line EN1. In this way, the first control signal line EN1 can transmit the received level signal to the first control end of the first first gating unit Q1, so that the first end of the first first gating unit Q1 is connected to or disconnected from the second end thereof, thereby making the first test signal line VT_1 electrically connected to or insulated from the common voltage signal line COM. Similarly, the first end of the second first gating unit Q1 is electrically connected to the second test signal line VT_2, the second end of the second first gating unit Q1 is electrically connected to the common voltage signal line COM, and the first control end of the second first gating unit Q1 is electrically connected to the first control signal line EN1. In this way, the first control signal line EN1 can transmit the received level signal to the first control end of the second first gating unit Q1, so that the first end of the second first gating unit Q1 is connected to or disconnected from the second end thereof, thereby making the second test signal line VT_2 electrically connected to or insulated from the common voltage signal line COM. Similarly, the first end of the third first gating unit Q1 is electrically connected to the third test signal line VT_3, the second end of the third first gating unit Q1 is electrically connected to the common voltage signal line COM, and the first control end of the third first gating unit Q1 is electrically connected to the first control signal line EN1. In this way, the first control signal line EN1 can transmit the received level signal to the first control end of the third first gating unit Q1, so that the first end of the third first gating unit Q1 is connected to or disconnected from the second end thereof, thereby making the third test signal line VT_3 electrically connected to or insulated from the common voltage signal line COM. It should be noted that the first control end of the first first gating unit Q1, the first control end of the second first gating unit Q1, and the first control end of the third first gating unit Q1 are connected to different first control signal lines EN1 respectively, that is, three first control signal lines EN1 should be arranged correspondingly for the three first gating units Q1. In this way, by arranging a plurality of first control signal lines EN1 to control the turn-on or turn-off of the corresponding first gating units Q1, it is possible to avoid the problem that the electrical connection relationship between the test signal line VT and the common voltage signal line COM fails or is uncontrollable due to the disconnection of some of the first control signal lines EN1.

In addition, it can be understood that the first test signal line VT_1 and the common voltage signal line COM are electrically connected through a first gating unit Q1, but the first test signal line VT_1 and the common voltage signal line COM can also be electrically connected through multiple first gating units Q1, that is, multiple first gating units Q1 are correspondingly arranged. This embodiment is only for example but not for the purpose of limitation here. The second test signal line VT_2 and the common voltage signal line COM can also be electrically connected through multiple first gating units Q1, and the third test signal line VT_3 and the common voltage signal line COM can also be electrically connected through multiple first gating units Q1.

In the embodiment shown in FIG. 6, the first control end of the first first gating unit Q1, the first control end of the second first gating unit Q1, and the first control end of the third first gating unit Q1 are all connected to the same first control signal line EN1, that is, only one first control signal line EN1 is correspondingly arranged for the three first gating units Q1. It can be understood that the control of the on or off of the multiple first gating units Q1 in the first gating circuit SW1 is simultaneous, and only one first control signal line EN1 is used to receive the level signal so that the multiple first gating units Q1 are simultaneously turned on or off, thereby facilitating improvement of the stability and reliability of the electrical connection between the test signal line VT and the common voltage signal line COM. In addition, the quantity of first control signal lines EN1 required to be set in FIG. 6 is small, which can further save space in the border area NA, and is conducive to the design of a narrow border.

The first gating circuit SW1 shown in FIG. 7 includes a first gating unit Q1. The test signal line VT includes a first test signal line VT_1, a second test signal line VT_2, and a third test signal line VT_3.

Exemplarily, in another specific embodiment, the first end of the first gating unit Q1 is electrically connected to the first test signal line VT_1, the second test signal line VT_2, and the third test signal line VT_3 each, the second end of the first gating unit Q1 is electrically connected to the common voltage signal line COM, and the first control end of the first gating unit Q1 is electrically connected to the first control signal line EN1, in this way, the first control signal line EN1 can transmit the received level signal to the first control end of the first gating unit Q1, so that the first end of the first gating unit Q1 is connected or disconnected with the second end, thereby electrically connecting or insulating the first test signal line VT_1, the second test signal line VT_2, and the third test signal line VT_3 each to or from the common voltage signal line COM.

In the embodiment shown in FIG. 7, the first test signal line VT_1, the second test signal line VT_2, and the third test signal line VT_3 each are electrically connected to the first end of the same first gating unit Q1, that is, only one first gating unit Q1 is arranged corresponding to the three test signal lines VT. It can be understood that the electrical connection or insulation between the multiple test signal lines VT and the common voltage signal line COM is controlled simultaneously, and only one first control signal line EN1 is used to receive the level signal to turn on or off the corresponding first gating unit Q1, thereby facilitating the improvement of the efficiency of the electrical connection between the test signal line VT and the common voltage signal line COM. In addition, the quantity of the first control signal lines EN1 and the quantity of the first gating units Q1 required to be set in FIG. 7 are both small, which can further save space in the border area NA and is conducive to the realization of a narrow border design.

Optionally, referring to FIGS. 5, 6 and 7, the first gating unit Q1 is an N-type channel transistor or a P-type channel transistor. In this way, the type of the active level signal or inactive level signal transmitted to the first gating unit Q1 by the first control signal line EN1 is related to the channel type of the first gating unit Q1.

Exemplarily, when the first gating unit Q1 is an N-type channel transistor, the active level signal transmitted by the first control signal line EN1 is a high level signal, and the first gating unit Q1 can control the corresponding test signal line VT and the common voltage signal line COM to be connected according to the high level signal; the inactive level signal transmitted by the first control signal line EN1 is a low level signal, and the first gating unit Q1 can control the corresponding test signal line VT and the common voltage signal line COM to be disconnected according to the low level signal. Exemplarily, when the first gating unit Q1 is a P-type channel transistor, the active level signal transmitted by the first control signal line EN1 is a low level signal, and the first gating unit Q1 can control the corresponding test signal line VT and the common voltage signal line COM to be connected according to the low level signal; the inactive level signal transmitted by the first control signal line EN1 is a high level signal, and the first gating unit Q1 can control the corresponding test signal line VT and the common voltage signal line COM to be disconnected according to the high level signal. Exemplarily, the low level signal can be a VGL signal in the display panel. During the use stage of the display panel, the VGL signal line in the display panel can be electrically connected to the control end of the first gating unit Q1, that is, the gate of the P-type channel transistor, thereby avoiding the need to add a control signal port for the first gating unit Q1 on the driver chip, and there is no need to arrange an additional control signal line in the display panel, which helps to simplify the chip design and panel structure. In addition, the first gating unit Q1 is arranged as a P-type channel transistor, and during the use stage of the display panel, a low level signal can be used to control its conduction, thereby helping to reduce the voltage of the control signal of the first gating unit Q1 and reduce the power consumption of the panel. In FIG. 5, FIG. 6 and FIG. 7, the first gating unit Q1 is drawn as a P-type channel transistor as an example. This embodiment is only for example but not for the purpose of limitation.

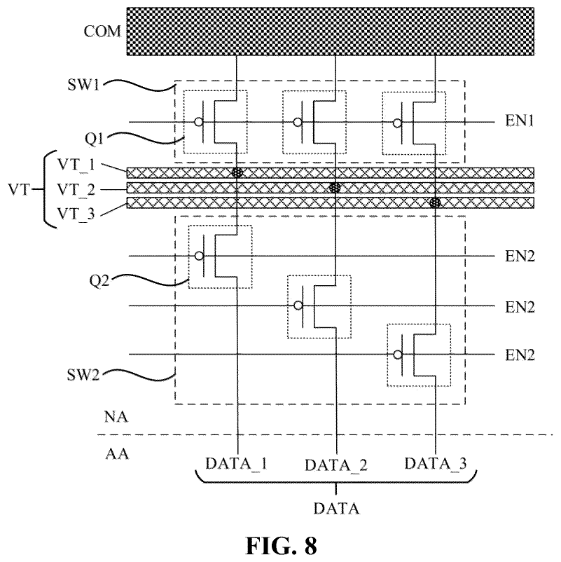

Optionally, FIG. 8 is a schematic structural diagram of another display panel provided by an embodiment of the present disclosure. As shown in FIG. 8, the border area NA also includes a second gating circuit SW2 and a second control signal line EN2; the second gating circuit SW2 is electrically connected to the second control signal line EN2, the test signal line VT and the data signal line DATA each; the second control signal line EN2 and the second gating circuit SW2 are configured so that: during the test stage of the display panel, the second control signal line EN2 receives an active level signal, and the second gating circuit SW2 controls the test signal line VT and the data signal line DATA to be connected according to the active level signal; during the use stage of the display panel, the second control signal line EN2 receives an inactive level signal, and the second gating circuit SW2 controls the test signal line VT and the data signal line DATA to be disconnected according to the inactive level signal.

Specifically, in the test stage of the display panel, the second control signal line EN2 can receive an active level signal, and the second control signal line EN2 is electrically connected to the second gating circuit SW2, so the second control signal line EN2 can transmit the active level signal to the second gating circuit SW2, and the second gating circuit SW2 can be turned on/form a closed path according to the active level signal. The second gating circuit SW2 is electrically connected to the test signal line VT and the data signal line DATA each, so the second gating circuit SW2 can also establish conductivity between the test signal line VT and the data signal line DATA to achieve the electrical connection between the test signal line VT and the data signal line DATA. In this way, in the test stage of the display panel, the second gating circuit SW2 is controlled to be turned on, and the test signal line VT can perform VT tests on sub-pixels of multiple colors via the data signal line DATA; in the use stage of the display panel, the second control signal line EN2 receives an inactive level signal, and the second control signal line EN2 is electrically connected to the second gating circuit SW2, so the second control signal line EN2 can transmit the inactive level signal to the second gating circuit SW2, and the second gating circuit SW2 is non-conductive/turned off/forms an open circuit according to the inactive level signal. The second gating circuit SW2 is electrically connected to the test signal line VT and the data signal line DATA each, and the second gating circuit SW2 can also disconnect the test signal line VT from the data signal line DATA, which corresponds to an insulation relationship between the test signal line VT and the data signal line DATA. In this way, in the use stage of the display panel, and the second gating circuit SW2 is controlled to be turned off, so the test signal line VT and the data signal line DATA have no electrical connection relationship, the test signal line VT does not need to continue to be used for VT testing, and the influence of the test signal line VT on the normal display process can also be avoided.

In addition, it should be noted that the present embodiment is drawn here by taking as an example the common voltage signal line COM including the second common voltage signal line COM_2 and controlling the electrical connection relationship between the test signal line VT and the data signal line DATA, which is only for example but not for purpose of limitation. Exemplarily, the common voltage signal line COM may also include the first common voltage signal line COM_1.

In addition, the border area NA includes a first gating circuit SW1, a first control signal line EN1, a second gating circuit SW2, and a second control signal line EN2. In the test stage of the display panel, the first control signal line EN1 receives an inactive level signal, and the first gating circuit SW1 can control the test signal line VT and the common voltage signal line COM to be disconnected according to the inactive level signal. At the same time, the second control signal line EN2 receives an active level signal, and the second gating circuit SW2 can control the test signal line VT and the data signal line DATA to be connected according to the active level signal, and in the use stage of the display panel, the first control signal line EN1 receives an active level signal, and the first gating circuit SW1 controls the test signal line VT and the common voltage signal line COM to be connected according to the active level signal. At the same time, the second control signal line EN2 receives an inactive level signal, and the second gating circuit SW2 controls the test signal line VT and the data signal line DATA to be disconnected according to the inactive level signal. In this way, the test stage and the use stage of the display panel do not interfere with each other. The test signal line VT can be used in the test stage to play a role in VT testing, and the test signal line VT can also be used in the use stage to play a role in voltage compensation and detection.

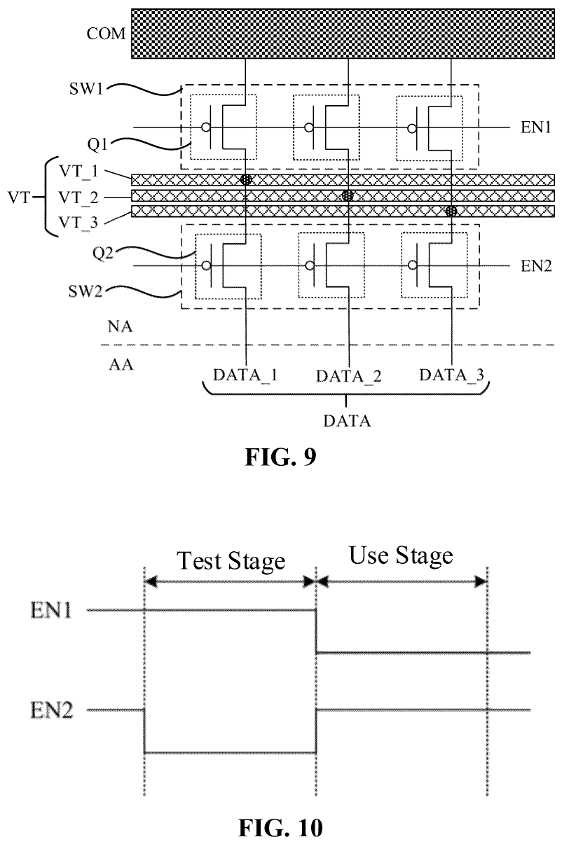

Further, still referring to FIG. 8, the second gating circuit SW2 includes multiple second gating units Q2, each including a third end, a fourth end and a second control end; the data signal line DATA includes a first data signal line DATA_1, a second data signal line DATA_2 and a third data signal line DATA_3; the test signal line VT includes a first test signal line VT_1, a second test signal line VT_2 and a third test signal line VT_3; the first test signal line VT_1 and the first data signal line DATA_1 are connected to the third end and the fourth end of the same second gating unit Q2 respectively; the second test signal line VT_2 and the second data signal line DATA_2 are connected to the third end and the fourth end of the same second gating unit Q2 respectively; the third test signal line VT_3 and the third data signal line DATA_3 are connected to the third end and the fourth end of the same second gating unit Q2 respectively; the second control ends of different second gating units Q2 are connected to different second control signal lines EN2. FIG. 9 is a schematic structural diagram of another display panel provided by an embodiment of the present disclosure. As shown in FIG. 9, the second gating circuit SW2 includes multiple second gating units Q2, each including a third end, a fourth end, and a second control end; the data signal line DATA includes a first data signal line DATA_1, a second data signal line DATA_2, and a third data signal line DATA_3; the test signal line VT includes a first test signal line VT_1, a second test signal line VT_2, and a third test signal line VT_3; the first test signal line VT_1 and the first data signal line DATA_1 are connected to the third end and the fourth end of a same second gating unit Q2 respectively; the second test signal line VT_2 and the second data signal line DATA_2 are connected to the third end and the fourth end of a same second gating unit Q2 respectively; the third test signal line VT_3 and the third data signal line DATA_3 are connected to the third end and the fourth end of a same second gating unit Q2 respectively; the second control ends of different second gating units Q2 are connected to the same second control signal line EN2.

Specifically, the second gating circuit SW2 shown in FIG. 8 includes a plurality of second gating units Q2. Exemplarily, the second gating circuit SW2 may include three second gating units Q2 (from left to right, the first second gating unit Q2, the second second gating unit Q2, and the third second gating unit Q2). Of course, it can be understood that this embodiment is only an example of the quantity setting of the second gating unit Q2, and is not limited. The data signal line DATA includes a first data signal line DATA_1, a second data signal line DATA_2, and a third data signal line DATA_3. Exemplarily, the first data signal line DATA_1, the second data signal line DATA_2, and the third data signal line DATA_3 are electrically connected to sub-pixels in different columns, respectively. The test signal line VT includes a first test signal line VT_1, a second test signal line VT_2, and a third test signal line VT_3.

Exemplarily, in a specific embodiment, the third end of the first second gating unit Q2 is electrically connected to the first test signal line VT_1, the fourth end of the first second gating unit Q2 is electrically connected to the first data signal line DATA_1, and the second control end of the first second gating unit Q2 is electrically connected to the second control signal line EN2. In this way, the second control signal line EN2 can transmit the received level signal to the second control end of the first second gating unit Q2, so that the third end and the fourth end of the first second gating unit Q2 are connected or disconnected, thereby electrically connecting or insulating the first test signal line VT_1 to or from the first data signal line DATA_1. Similarly, the third end of the second second gating unit Q2 is electrically connected to the second test signal line VT_2, the fourth end of the second second gating unit Q2 is electrically connected to the second data signal line DATA_2, and the second control end of the second second gating unit Q2 is electrically connected to the second control signal line EN2. In this way, the second control signal line EN2 can transmit the received level signal to the second control end of the second second gating unit Q2, so that the third end and the fourth end of the second second gating unit Q2 are connected or disconnected, thereby electrically connecting or insulating the second test signal line VT_2 to or from the second data signal line DATA_2. Similarly, the third end of the third second gating unit Q2 is electrically connected to the third test signal line VT_3, the fourth end of the third second gating unit Q2 is electrically connected to the third data signal line DATA_3, and the second control end of the third second gating unit Q2 is electrically connected to the second control signal line EN2. In this way, the second control signal line EN2 can transmit the received level signal to the second control end of the third second gating unit Q2, so that the third end and the fourth end of the third second gating unit Q2 are connected or disconnected, thereby electrically connecting or insulating the third test signal line VT_3 to or from the third data signal line DATA_3. It should be noted that the second control end of the first second gating unit Q2, the second control end of the second second gating unit Q2, and the second control end of the third second gating unit Q2 are connected to different second control signal lines EN2 respectively, that is, the three second gating units Q2 should be provided with three second control signal lines EN2 accordingly. In addition, it can be understood that the first test signal line VT_1 and the first data signal line DATA_1 are electrically connected through a second gating unit Q2, and the first test signal line VT_1 and the first data signal line DATA_1 can also be electrically connected through multiple second gating units Q2, that is, multiple second gating units Q2 are correspondingly provided. This embodiment is only for example but not for the purpose of limitation here. The second test signal line VT_2 and the second data signal line DATA_2 can also be electrically connected through multiple second gating units Q2, and the third test signal line VT_3 and the third data signal line DATA_3 can also be electrically connected through multiple second gating units Q2.

In the embodiment shown in FIG. 9, the second control end of the first second gating unit Q2, the second control end of the second second gating unit Q2, and the second control end of the third second gating unit Q2 are all connected to the same second control signal line EN2, that is, only one second control signal line EN2 is correspondingly provided for the three second gating units Q2. It can be understood that the control of the on or off of the multiple second gating units Q2 in the second gating circuit SW2 is simultaneous, and only one second control signal line EN2 is used to receive the level signal, so that the multiple second gating units Q2 are simultaneously turned on or off, which is conducive to improving the stability and reliability of the electrical connection between the test signal line VT and the data signal line DATA. In addition, the quantity of second control signal lines EN2 required to be set in FIG. 9 is small, which can further save space in the border area NA, thereby facilitating the realization of the design of a narrow border.

Optionally, continuing to refer to FIG. 8 and FIG. 9, the second gating unit Q2 is an N-type channel transistor or a P-type channel transistor. In this way, the type of the active level signal or inactive level signal transmitted by the second control signal line EN2 to the second gating unit Q2 is related to the channel type of the second gating unit Q2.

Exemplarily, when the second gating unit Q2 is an N-type channel transistor, the active level signal transmitted by the second control signal line EN2 is a high level signal, and the second gating unit Q2 can control the corresponding test signal line VT and the data signal line DATA to be connected according to the high level signal; the inactive level signal transmitted by the second control signal line EN2 is a low level signal, and the second gating unit Q2 can control the corresponding test signal line VT and the data signal line DATA to be disconnected according to the low level signal. Exemplarily, when the second gating unit Q2 is a P-type channel transistor, the active level signal transmitted by the second control signal line EN2 is a low level signal, and the second gating unit Q2 can control the corresponding test signal line VT and the data signal line DATA to be connected according to the low level signal; the inactive level signal transmitted by the second control signal line EN2 is a high level signal, and the second gating unit Q2 can control the corresponding test signal line VT and the data signal line DATA to be disconnected according to the high level signal. Similarly, the low level signal here can also be a VGL signal in the display panel. In the test stage of the display panel, the VGL signal line in the display panel can be electrically connected to the control end of the second gating unit Q2, that is, the gate of the P-type channel transistor, thereby avoiding the need to add a control signal port for the second gating unit Q2 on the driver chip, and there is no need to arrange an additional control signal line in the display panel, which helps to simplify the chip design and panel structure. In addition, with the second gating unit Q2 provided as a P-type channel transistor, in the test stage of the display panel, a low level signal can be used to control its turning-on, thereby helping to reduce the voltage of the control signal of the second gating unit Q2 and reduce the power consumption in the test stage.

Exemplarily, in a specific embodiment, FIG. 10 is a time sequence diagram of the first control signal line and the second control signal line of the display panel shown in FIG. 9. As shown in FIG. 9 and FIG. 10, the border area NA includes a first control signal line EN1, a first gating circuit SW1, a second control signal line EN2 and a second gating circuit SW2. The first control signal line EN1 is electrically connected to the first gating circuit SW1, and the second control signal line EN2 is electrically connected to the second gating circuit SW2. The first gating circuit SW1 includes a first gating unit Q1, and the second gating circuit SW2 includes a second gating unit Q2. The first gating unit Q1 and the second gating unit Q2 are the same, and the first gating unit Q1 and the second gating unit Q2 can be P-type channel transistors. Correspondingly, the active level signal of the first gating unit Q1 and the second gating unit Q2 is a low level signal, and the inactive level signal of the first gating unit Q1 and the second gating unit Q2 is a high level signal. In the test stage of the display panel, the first control signal line EN1 receives the high level signal, and the first gating unit Q1 can control the test signal line VT and the common voltage signal line COM to be disconnected according to the high level signal, and the second control signal line EN2 receives the low level signal, and the second gating unit Q2 can control the test signal line VT and the data signal line DATA to be connected according to the low level signal. In the use stage of the display panel, the first control signal line EN1 receives the low level signal, and the first gating unit Q1 can control the test signal line VT and the common voltage signal line COM to be connected according to the low level signal, and the second control signal line EN2 receives the high level signal, and the second gating unit Q2 can control the test signal line VT and the data signal line DATA to be disconnected according to the high level signal. FIG. 9 is drawn by taking the first gating unit Q1 and the second gating unit Q2 as P-type channel transistors as an example. This embodiment is only for example here but not for the purpose of limitation. Of course, the first gating unit Q1 and the second gating unit Q2 can also be both N-type channel transistors. Similarly, FIG. 8 is drawn by taking the first gating unit Q1 and the second gating unit Q2 as P-type channel transistors as an example. This embodiment is only for example here but not for the purpose of limitation. Of course, the first gating unit Q1 and the second gating unit Q2 can also be both N-type channel transistors.

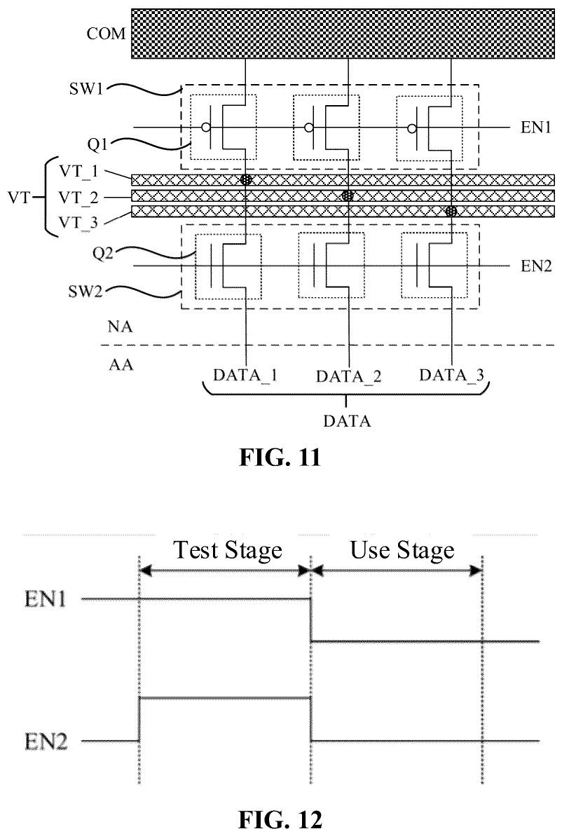

Exemplarily, in another specific embodiment, FIG. 11 is a schematic structural diagram of another display panel provided by an embodiment of the present disclosure, and FIG. 12 is a time sequence diagram of the first control signal line and the second control signal line of the display panel shown in FIG. 11. As shown in FIG. 11 and FIG. 12, the border area NA includes a first control signal line EN1, a first gating circuit SW1, a second control signal line EN2 and a second gating circuit SW2. The first control signal line EN1 is electrically connected to the first gating circuit SW1, and the second control signal line EN2 is electrically connected to the second gating circuit SW2, where the first gating circuit SW1 includes a first gating unit Q1, and the second gating circuit SW2 includes a second gating unit Q2. The first gating unit Q1 and the second gating unit Q2 are different. The first gating unit Q1 can be a P-type channel transistor, and the second gating unit Q2 can be an N-type channel transistor. Correspondingly, the active level signal of the first gating unit Q1 is a low level signal, the inactive level signal of the first gating unit Q1 is a high level signal, the active level signal of the second gating unit Q2 is a high level signal, and the inactive level signal of the second gating unit Q2 is a low level signal. In the test stage of the display panel, the first control signal line EN1 receives the high level signal, and the first gating unit Q1 can control the test signal line VT and the common voltage signal line COM to be disconnected according to the high level signal, and the second control signal line EN2 receives the high level signal, and the second gating unit Q2 can control the test signal line VT and the data signal line DATA to be connected according to the high level signal. In the use stage of the display panel, the first control signal line EN1 receives the low level signal, and the first gating unit Q1 can control the test signal line VT and the common voltage signal line COM to be connected according to the low level signal, and the second control signal line EN2 receives the low level signal, and the second gating unit Q2 can control the test signal line VT and the data signal line DATA to be disconnected according to the low level signal. FIG. 11 is drawn by taking the first gating unit Q1 as a P-type channel transistor and the second gating unit Q2 as an N-type channel transistor as an example. This embodiment is only for example here but not for the purpose of limitation. Of course, the first gating unit Q1 can be an N-type channel transistor and the second gating unit Q2 can be a P-type channel transistor. Similarly, FIG. 8 is drawn by taking the first gating unit Q1 and the second gating unit Q2 as P-type channel transistors as an example. This embodiment is only for example here but not for the purpose of limitation. Of course, the first gating unit Q1 may be an N-type channel transistor and the second gating unit Q2 may be a P-type channel transistor.

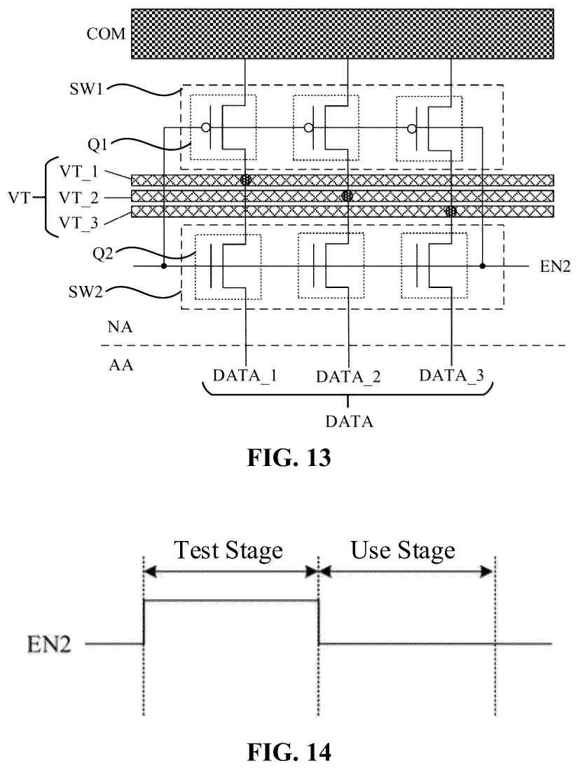

On the basis of the embodiments of FIG. 11 and FIG. 12, optionally, FIG. 13 is a schematic structural diagram of another display panel provided by an embodiment of the present disclosure, and FIG. 14 is a time sequence diagram of the first control signal line and the second control signal line of the display panel shown in FIG. 13. As shown in FIG. 13 and FIG. 14, the second control signal line EN2 is also used as the first control signal line EN1, and the second control signal line EN2 is electrically connected to the first gating circuit SW1; the second control signal line EN2, the first gating circuit SW1 and the second gating circuit SW2 are configured so that: during the test stage of the display panel, the second control signal line EN2 receives the first level signal as the inactive level signal of the first gating circuit SW1 and the active level signal of the second gating circuit SW2, the first gating circuit SW1 controls the test signal line VT and the common voltage signal line COM to be disconnected according to the first level signal, and the second gating circuit SW2 controls the test signal line VT and the data signal line DATA to be connected according to the first level signal; in the use stage of the display panel, the second control signal line EN2 receives the second level signal as the active level signal of the first gating circuit SW1 and the inactive level signal of the second gating circuit SW2, the first gating circuit SW1 controls the test signal line VT and the common voltage signal line COM to be connected according to the second level signal, and the second gating circuit SW2 controls the test signal line VT and the data signal line DATA to be disconnected according to the second level signal.

Specifically, the first control signal line EN1 is electrically connected to the first gating circuit SW1, and the first control signal line EN1 can transmit the received level signal to the first gating circuit SW1, and the first gating circuit SW1 can be turned on or off according to the level signal. The second control signal line EN2 is electrically connected to the second gating circuit SW2, and the second control signal line EN2 can transmit the received level signal to the second gating circuit SW2, and the second gating circuit SW2 can be turned on or off according to the level signal. The second control signal line EN2 is set to be also used as the first control signal line EN1, so that the second control signal line EN2 can also be electrically connected to the first gating circuit SW1. That is, the first gating circuit SW1 and the second gating circuit SW2 share a second control signal line EN2, and there is no need to arrange the first control signal line EN1 additionally, which is also conducive to reducing the left border area and the right border area of the display panel. In the test stage of the display panel, the second control signal line EN2 can receive a first level signal, and the second control signal line EN2 is electrically connected to the first gating circuit SW1 and the second gating circuit SW2 each, so the second control signal line EN2 can transmit the first level signal to the first gating circuit SW1 and the second gating circuit SW2, and the first level signal can be used as an inactive level signal of the first gating circuit SW1 and an active level signal of the second gating circuit SW2, so that the first gating circuit SW1 can control the corresponding test signal line VT and the common voltage signal line COM to be disconnected according to the first level signal, and the second gating circuit SW2 can control the corresponding test signal line VT and the data signal line DATA to be connected according to the first level signal. During the use stage of the display panel, the second control signal line EN2 can receive the second level signal, and the second control signal line EN2 is electrically connected to the first gating circuit SW1 and the second gating circuit SW2 each, so the second control signal line EN2 can transmit the second level signal to the first gating circuit SW1 and the second gating circuit SW2, and the second level signal can be used as the active level signal of the first gating circuit SW1 and the inactive level signal of the second gating circuit SW2, so that the first gating circuit SW1 can control the test signal line VT and the common voltage signal line COM to be connected according to the second level signal, and the second gating circuit SW2 can control the test signal line VT and the data signal line DATA to be disconnected according to the second level signal.

Exemplarily, in a specific embodiment, the first gating circuit SW1 includes a first gating unit Q1, and the first gating unit Q1 can be an N-type channel transistor or a P-type channel transistor. The second gating circuit SW2 includes a second gating unit Q2, and the second gating unit Q2 can be an N-type channel transistor or a P-type channel transistor. In this embodiment, the transistor channel types of the first gating unit Q1 and the second gating unit Q2 should be different. Optionally, the first gating unit Q1 can be a P-type channel transistor, and the second gating unit Q2 can be an N-type channel transistor, and the first level signal and the second level signal are two level signals. Exemplarily, the first level signal can be a high level signal, and the second level signal can be a low level signal. In this way, in the test stage of the display panel, the second control signal line EN2 receives a high level signal to turn off the corresponding first gating unit Q1 and turn on the second gating unit Q2. In the use stage of the display panel, the second control signal line EN2 receives a low level signal to turn on the corresponding first gating unit Q1 and turn off the second gating unit Q2. In addition, it can be understood that the first gating unit Q1 and the second gating unit Q2 are both chosen to use transistors, the LTPS electron mobility is high, and the LTPS applicability is stronger.

In addition, exemplarily, the first control signal line EN1 can also be set to be also used as the second control signal line EN2, so that the first control signal line EN1 can also be electrically connected to the second gating circuit SW2. That is, the first gating circuit SW1 and the second gating circuit SW2 share a first control signal line EN1, and there is no need to additionally arrange the second control signal line EN2, which also helps to reduce the left border area and the right border area of the display panel.

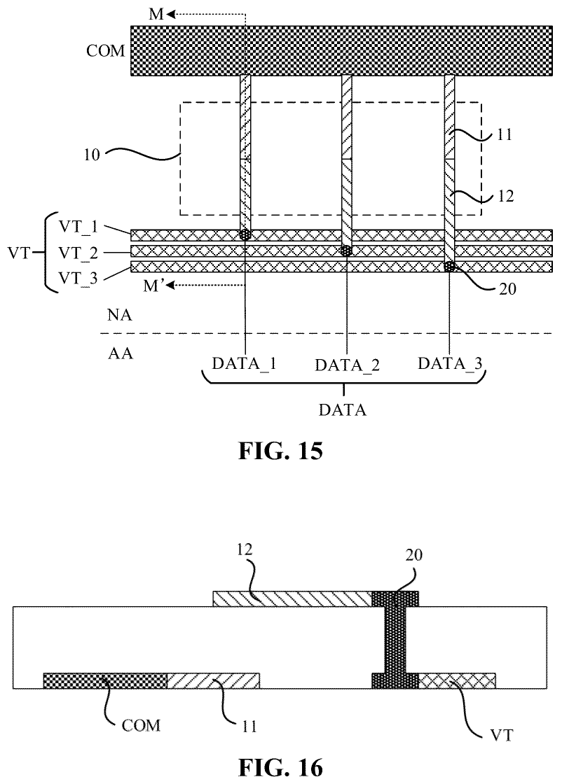

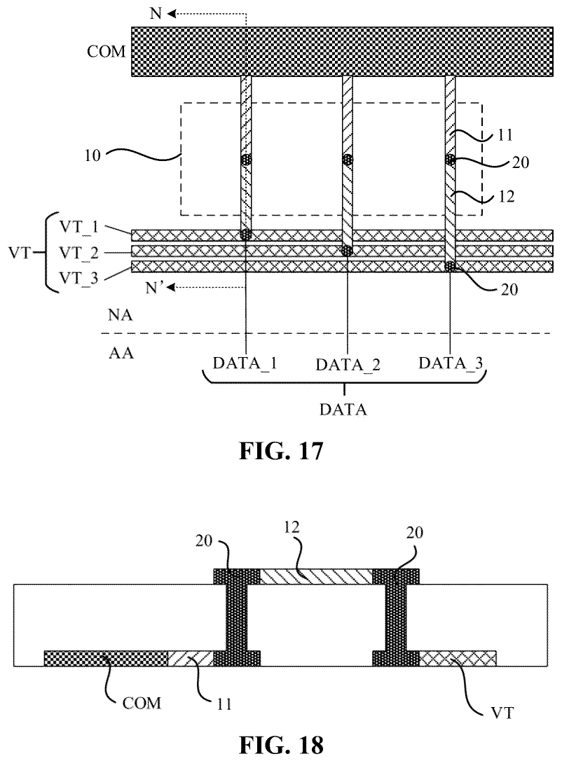

Optionally, FIG. 15 is a schematic structural diagram of a top view of a display panel in a test stage provided by an embodiment of the present disclosure, and FIG. 16 is a schematic diagram of a cross-section in the MM′ direction of the display panel in the test stage shown in FIG. 15. As shown in FIG. 15 and FIG. 16, the border area NA also includes a connection structure 10 and the test signal line VT, the connection structure 10 and the common voltage signal line COM span different film layers, and one end of the connection structure 10 is electrically connected to the test signal line VT, and the other end is electrically connected to the common voltage signal line COM; in the test stage of the display panel, respective parts of the test signal line VT, the connection structure 10 and the common voltage signal line COM located in different film layers have overlapping projections and are insulated. FIG. 17 is a schematic structural diagram of a top view of a display panel during the use stage provided by an embodiment of the present disclosure, and FIG. 18 is a schematic diagram of a cross-section in the NN′ direction of the display panel during the use stage shown in FIG. 17. As shown in FIG. 17 and FIG. 18, during the use stage of the display panel, the respective parts of the test signal line VT, the connection structure 10 and the common voltage signal line COM located in different film layers are electrically connected in sequence through vias 20.

Specifically, the border area NA also includes a connection structure 10. This embodiment is only for the case where there is established an electrical connection/insulation between the test signal line VT and the common voltage signal line COM, which can be achieved by the first gating circuit SW1 or by the connection structure 10. The test signal line VT, the connection structure 10, and the common voltage signal line COM span different film layers, and one end of the connection structure 10 is electrically connected to the test signal line VT, and the other end is electrically connected to the common voltage signal line COM. Exemplarily, the test signal line VT and the common voltage signal line COM are located in the same film layer, and the connection structure 10 can span the film layer in a direction perpendicular to a light-emitting surface of the display panel to achieve the electrical connection between the test signal line VT and the common voltage signal line COM. During the test stage of the display panel, respective parts of the test signal line VT, the connection structure 10 and the common voltage signal line COM located in different film layers have overlapping projections and are insulated. In this way, the test signal line VT and the common voltage signal line COM are insulated, and the test signal line VT can play a role in VT testing, avoiding the influence of the common voltage signal line COM during the VT test process. In addition, since the respective parts of the test signal line VT, the connection structure 10 and the common voltage signal line COM located in different film layers have overlapping projections, vias 20 can be formed in the overlapping areas of the projections. The via 20 spans the film layers, and establishes an electrical connection between an area where the test signal line VT is located and an area where the common voltage signal line COM is located. During the use stage of the display panel, the respective parts of the test signal line VT, the connection structure 10 and the common voltage signal line COM located in different film layers are electrically connected in sequence through vias 20. In this way, the test signal line VT and the common voltage signal line COM are electrically connected, and the test signal line VT can play a role in voltage compensation or detection. That is, this embodiment uses the connection structure 10 and the via 20 to achieve the connection or disconnection between the test signal line VT and the common voltage signal line COM, reducing the setting quantity of related transistor elements and signal lines, and also helping to reduce the left border area and the right border area of the display panel.

Furthermore, it should be noted that the positional relationship, and settings of film layer, length, and width of the test signal line VT and the common voltage signal line COM, and the positions, and settings of film layer, and size of the vias 20 in the cross-sectional schematic diagrams shown in FIG. 16 and FIG. 18 are all exemplary, and are only intended to illustratively provide here an embodiment that respective parts of the test signal line VT, the connection structure 10 and the common voltage signal line COM located in different film layers have overlapping projections, and the vias 20 are formed in the overlapping locations of projections of the test signal line VT, the connection structure 10 and the common voltage signal line COM located in different film layers.

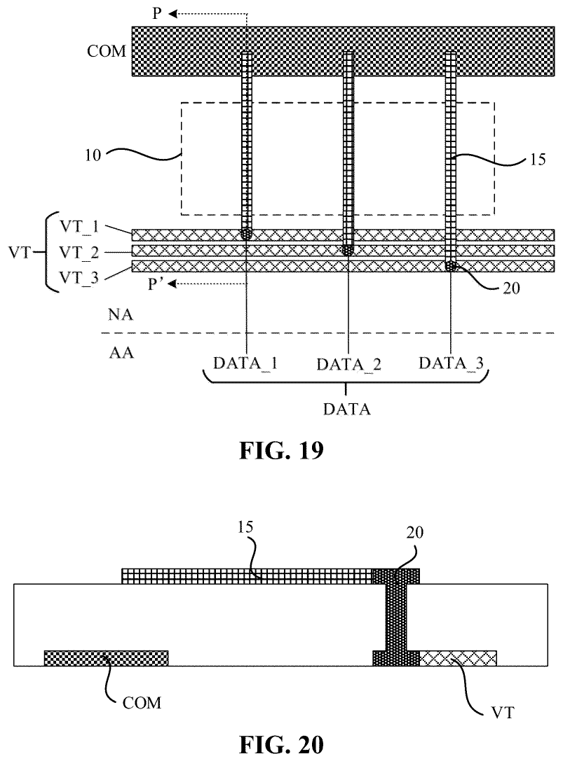

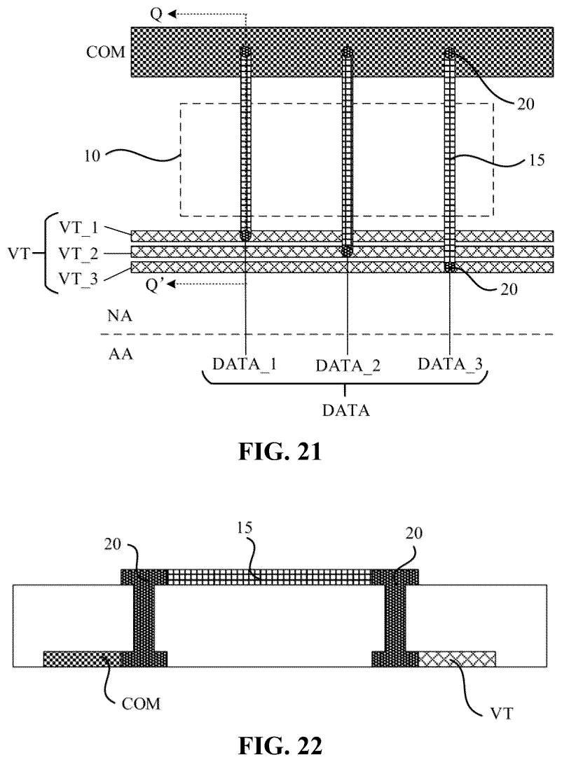

In addition, in a specific embodiment, the test signal line VT and the common voltage signal line COM in the same film layer can be electrically connected through at least one connection structure 10 and at least one via 20 spanning the film layer. Exemplarily, one end of the connection structure 10 is electrically connected to the common voltage signal line COM, and the other end of the connection structure 10 is electrically connected to the test signal line VT. At least one via 20 spanning the film layer is provided between the two ends of the connection structure 10, so as to indirectly achieve the electrical connection between the test signal line VT and the common voltage signal line COM. Alternatively, exemplarily, one end of the connection structure 10 is electrically connected to the common voltage signal line COM, and at least parts of the one end of the connection structure 10 and the common voltage signal line COM located in different film layers have overlapping projections; the other end of the connection structure 10 is electrically connected to the test signal line VT (for example, the test signal line VT and the connection structure 10 may be electrically connected in advance through at least one via 20), and then at least one via 20 may be formed in the area where the connection structure 10 and the common voltage signal line COM have the overlapping projections, thereby indirectly achieving the electrical connection between the test signal line VT and the common voltage signal line COM. Exemplarily, FIG. 19 is a schematic structural diagram of a top view of another display panel in the test stage provided by an embodiment of the present disclosure, FIG. 20 is a schematic diagram of a cross-section in the PP′ direction of the display panel in the test stage shown in FIG. 19, FIG. 21 is a schematic structural diagram of a top view of another display panel in the use stage provided by an embodiment of the present disclosure, and FIG. 22 is a schematic diagram of a cross-section in the QQ′ direction of the display panel in the use stage shown in FIG. 21. As shown in FIG. 19-FIG. 22, the connection structure 10 includes a third connection line 15. One end of the third connection line 15 is electrically connected to the test signal line VT through a via 20, and the other end of the third connection line 15 extends in a direction where the common voltage signal line COM is located until there is an area where the third connection line 15 and the common voltage signal line COM have the overlapping projections. Still referring to FIG. 19 and FIG. 20, during the test stage of the display panel, at least parts of the third connection line 15 and the common voltage signal line COM located in different film layers have the overlapping projections and are insulated. Still referring to FIG. 21 and FIG. 22, during the use stage of the display panel, the at least parts of the third connection line 15 and the common voltage signal line COM located in different film layers are electrically connected through the vias 20, thereby achieving an electrical connection between the test signal line VT and the common voltage signal line COM. Alternatively, illustratively, one end of the third connection line 15 can be electrically connected to the common voltage signal line COM in advance through at least one via 20; the other end of the third connection line 15 is electrically connected to the test signal line VT, and at least parts of the other end of the third connection line 15 and the test signal line VT located in different film layers have the overlapping projections, so at least one via 20 can be formed in the area where the third connection line 15 and the test signal line VT have the overlapping projections, so as to indirectly achieve the electrical connection relationship between the test signal line VT and the common voltage signal line COM.

Optionally, continuing to refer to FIG. 15 and FIG. 16, the connection structure 10 includes a first connection line 11 and a second connection line 12, the first connection line 11 and the second connection line 12 are located in different film layers, the first end of the first connection line 11 is electrically connected to the common voltage signal line COM, and the first end of the second connection line 12 is electrically connected to the test signal line VT; the second end of the first connection line 11 and the second end of the second connection line 12 overlap in projection on the light emitting surface of the display panel; in the test stage of the display panel, the second end of the first connection line 11 and the second end of the second connection line 12 are insulated. Continuing to refer to FIG. 17 and FIG. 18, during the use stage of the display panel, the second end of the first connection line 11 and the second end of the second connection line 12 are electrically connected through the via 20.

Specifically, the connection structure 10 includes a first connection line 11 and a second connection line 12, and the first connection line 11 and the second connection line 12 are located in different film layers, where the first end of the first connection line 11 is electrically connected to the common voltage signal line COM, and the first connection line 11 and the common voltage signal line COM can be regarded as a whole. Exemplarily, the first connection line 11 and the common voltage signal line COM can be located in the same film layer, and the first end of the first connection line 11 and the common voltage signal line COM can be electrically connected by contact, or the first connection line 11 and the common voltage signal line COM can be located in different film layers, and the first end of the first connection line 11 and the common voltage signal line COM can be electrically connected through the via 20. This embodiment only exemplarily gives a schematic diagram of the first connection line 11 and the common voltage signal line COM being located in the same film layer. The first end of the second connection line 12 is electrically connected to the test signal line VT. The second connection line 12 and the test signal line VT can be regarded as a whole. Exemplarily, the second connection line 12 and the test signal line VT can be located in the same film layer, and the first end of the second connection line 12 and the test signal line VT can be electrically connected by contact, or the second connection line 12 and the test signal line VT can be located in different film layers, and the first end of the second connection line 12 and the test signal line VT can be electrically connected through a via 20. This embodiment only exemplarily gives a schematic diagram of the second connection line 12 and the test signal line VT being located in different film layers.

Still referring to FIG. 15 and FIG. 16, in the test stage of the display panel, the second end of the first connection line 11 and the second end of the second connection line 12 overlap in projection on the light-emitting surface of the display panel, and the second end of the first connection line 11 and the second end of the second connection line 12 are insulated. In this way, the first connection line 11 and the second connection line 12 are insulated, and then the test signal line VT and the common voltage signal line COM are insulated. The test signal line VT can play a role in VT testing, avoiding the influence of the common voltage signal line COM during the VT testing process. Also, since the second end of the first connection line 11 and the second end of the second connection line 12 have the overlapping projections on the light-emitting surface of the display panel, a via 20 can be formed in the overlapping projection area. The via 20 spans the film layer, and establishes an electrical connection relationship between the film layer where the first connection line 11 is located and the film layer where the second connection line 12 is located, thereby establishing an electrical connection relationship between the area where the test signal line VT is located and the area where the common voltage signal line COM is located. Continuing to refer to FIGS. 17 and 18, during the use stage of the display panel, the second end of the first connection line 11 and the second end of the second connection line 12 are electrically connected through the via 20, so that the common voltage signal line COM is electrically connected to the test signal line VT through the first connection line 11, the via 20, and the second connection line 12 in sequence, and the test signal line VT can play a role in voltage compensation or detection.

In addition, illustratively, the test signal line VT can be electrically connected to the common voltage signal line COM through a second connection line 12, a via 20, and a first connection line 11 in sequence, or the test signal line VT can be electrically connected to the common voltage signal line COM through corresponding multiple second connection lines 12, multiple vias 20, and multiple first connection lines 11. In this way, the quantity of connection line channels (referring to the connection channel of the first connection line 11, the via 20, and the second connection line 12) electrically connecting the test signal line VT and the common voltage signal line COM is reasonably increased, which can avoid the electrical connection failure between the test signal line VT and the common voltage signal line COM caused by poor contact of some connection line channels.

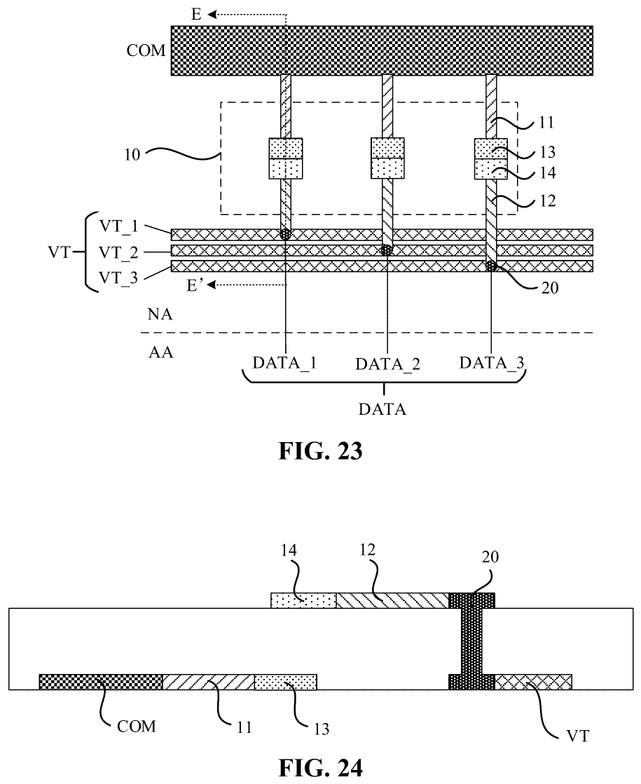

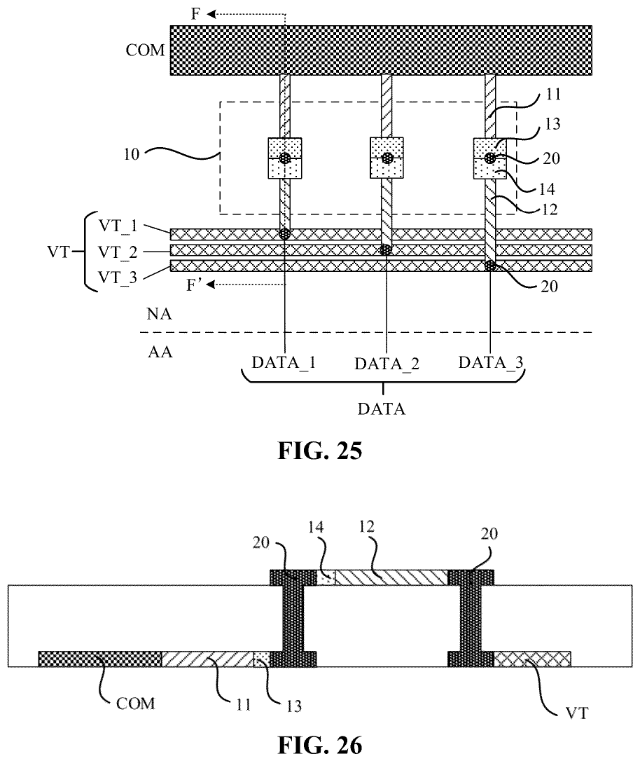

Optionally, FIG. 23 is a schematic structural diagram of a top view of another display panel in the test stage provided by an embodiment of the present disclosure, and FIG. 24 is a schematic diagram of a cross-section in the EE′ direction of the display panel in the test stage shown in FIG. 23. As shown in FIG. 23 and FIG. 24, the connection structure 10 includes a first connection line 11, a second connection line 12, a first bonding pad 13 and a second bonding pad 14. The first connection line 11 and the first bonding pad 13 are in the same layer, the second connection line 12 and the second bonding pad 14 are in the same layer, and the first connection line 11 and the second connection line 12 are located in different film layers; the first end of the first connection line 11 is electrically connected to the common voltage signal line COM, and the second end of the first connection line 11 is electrically connected to the first bonding pad 13; the first end of the second connection line 12 is electrically connected to the test signal line VT, and the second end of the second connection line 12 is electrically connected to the second bonding pad 14; the projections of the first bonding pad 13 and the second bonding pad 14 on the light emitting surface of the display panel overlap; in the test stage of the display panel, the first bonding pad 13 and the second bonding pad 14 are insulated. FIG. 25 is a schematic structural diagram of a top view of another display panel during the use stage provided by an embodiment of the present disclosure, and FIG. 26 is a schematic diagram of a cross-section in the FF′ direction of the display panel during the test stage shown in FIG. 25. As shown in FIG. 25 and FIG. 26, during the use stage of the display panel, the first bonding pad 13 and the second bonding pad 14 are electrically connected through the via 20.

Specifically, the connection structure 10 includes a first connection line 11, a second connection line 12, a first bonding pad 13, and a second bonding pad 14. The first connection line 11 and the first bonding pad 13 are in the same layer, the second connection line 12 and the second bonding pad 14 are in the same layer, and the first connection line 11 and the second connection line 12 are located in different film layers. Here the first end of the first connection line 11 is electrically connected to the common voltage signal line COM, and the second end of the first connection line 11 is electrically connected to the first bonding pad 13. The common voltage signal line COM, the first connection line 11 and the first bonding pad 13 can be regarded as a whole. Exemplarily, the first connection line 11 and the common voltage signal line COM can be located in the same film layer, and the first end of the first connection line 11 and the common voltage signal line COM can be electrically connected by contact, or the first connection line 11 and the common voltage signal line COM can be located in different film layers, and the first end of the first connection line 11 and the common voltage signal line COM can be electrically connected through a via 20. This embodiment only exemplarily provides a schematic diagram of the first connection line 11 and the common voltage signal line COM being located in the same film layer. The first end of the second connection line 12 is electrically connected to the test signal line VT, and the second end of the second connection line 12 is electrically connected to the second bonding pad 14. The test signal line VT, the second connection line 12 and the second bonding pad 14 can be regarded as a whole. Exemplarily, the second connection line 12 and the test signal line VT can be located in the same film layer, and the first end of the second connection line 12 and the test signal line VT can be electrically connected by contact. Alternatively, the second connection line 12 and the test signal line VT can be located in different film layers, and the first end of the second connection line 12 and the test signal line VT can be electrically connected through a via 20. This embodiment only exemplarily provides a schematic diagram of the second connection line 12 and the test signal line VT being located in different film layers.

Continuing to refer to FIG. 23 and FIG. 24, in the test stage of the display panel, the first bonding pad 13 and the second bonding pad 14 have the overlapping projections on the light-emitting surface of the display panel, and the first bonding pad 13 and the second bonding pad 14 are insulated, so that the first bonding pad 13 and the second bonding pad 14 are an insulated relationship, the first connection line 11 and the second connection line 12 are an insulated relationship, and then the test signal line VT and the common voltage signal line COM are an insulated relationship, and the test signal line VT can play a role in VT testing, avoiding the influence of the common voltage signal line COM during the VT testing process. In addition, since the first bonding pad 13 and the second boning pad 14 have the overlapping projections on the light-emitting surface of the display panel, a via 20 can be formed in the overlapping projection area, and the via 20 spans the film layer, and establishes an electrical connection relationship between the film layer where the first bonding pad 13 is located and the film layer where the second bonding pad 14 is located, that is, establishes an electrical connection relationship between the film layer where the first connection line 11 is located and the film layer where the second connection line 12 is located, and then establishes an electrical connection relationship between the area where the test signal line VT is located and the area where the common voltage signal line COM is located. Continuing to refer to FIG. 25 and FIG. 26, during the use stage of the display panel, the first bonding pad 13 and the second bonding pad 14 are electrically connected through the via 20, so that the common voltage signal line COM is electrically connected to the test signal line VT through the first connection line 11, the first bonding pad 13, the via 20, the second bonding pad 14, and the second connection line 12 in sequence, and the test signal line VT can play a role in voltage compensation or detection.

In addition, illustratively, the test signal line VT can be electrically connected to the common voltage signal line COM through a second connection line 12, a second bonding pad 14, a via 20, a first bonding pad 13, and a first connection line 11 in sequence, or the test signal line VT can be electrically connected to the common voltage signal line COM through corresponding multiple second connection lines 12, multiple second bonding pads 14, multiple vias 20, multiple first bonding pads 13, and multiple first connection lines 11. In this way, the quantity of connection line channels electrically connecting the test signal line VT and the common voltage signal line COM (referring to the connection channel of the first connection line 11, the first bonding pad 13, the via 20, the second bonding pad 14, and the second connection line 12) is reasonably increased, which can avoid electrical connection errors between the test signal line VT and the common voltage signal line COM due to poor contact of some connection line channels. In addition, the technical scheme of FIG. 23 to FIG. 26 (laser melting of the first bonding pad 13 and the second bonding pad 14 are directly performed to generate the via 20, so as to indirectly achieve the electrical connection between the first connection line 11 and the second connection line 12) can effectively reduce the difficulty of laser melting to generate the via 20.

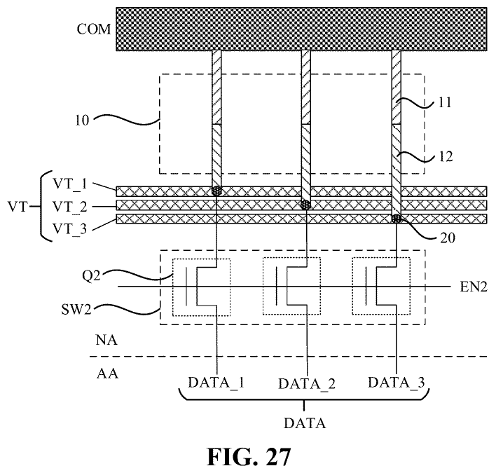

Optionally, FIG. 27 is a schematic structural diagram of another display panel provided by an embodiment of the present disclosure. As shown in FIG. 27, the border area NA also includes a second gating circuit SW2 and a second control signal line EN2; the second gating circuit SW2 is electrically connected to the second control signal line EN2, the test signal line VT and the data signal line DATA each; the second control signal line EN2 and the second gating circuit SW2 are configured so that: in the test stage of the display panel, the second control signal line EN2 receives an active level signal, and the second gating circuit SW2 controls the test signal line VT and the data signal line DATA to be connected according to the active level signal; in the use stage of the display panel, the second control signal line EN2 receives an inactive level signal, and the second gating circuit SW2 controls the test signal line VT and the data signal line DATA to be disconnected according to the inactive level signal.

Specifically, please refer to the above embodiments for the relevant content, which will not be repeated here.

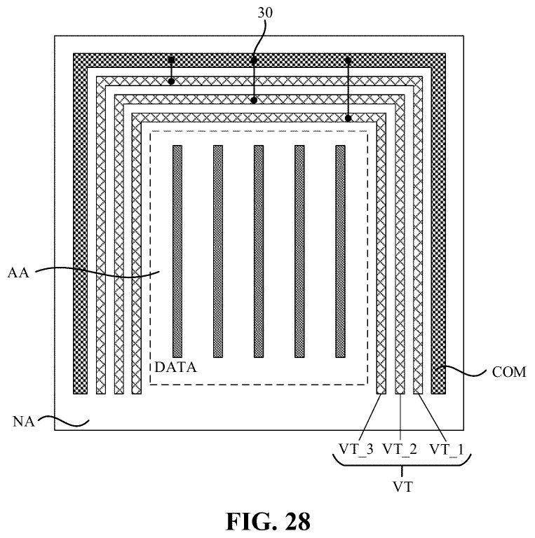

Optionally, FIG. 28 to FIG. 31 are schematic structural diagrams of four further display panels provided by embodiments of the present disclosure. As shown in FIG. 28 to FIG. 31, the number of test signal lines VT is at least two; each test signal line VT is electrically connected to the common voltage signal line COM through at least one connection position 30, and different test signal lines VT have different connection positions 30 on the common voltage signal line COM.

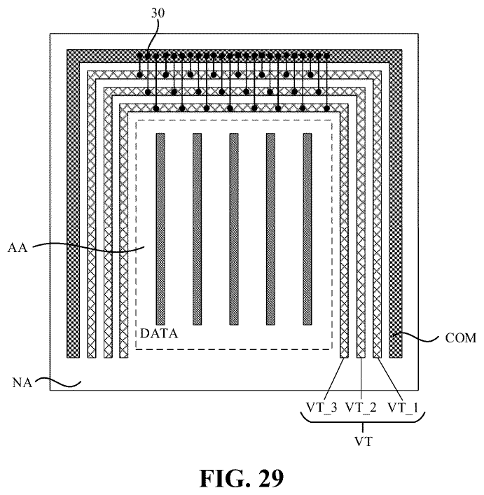

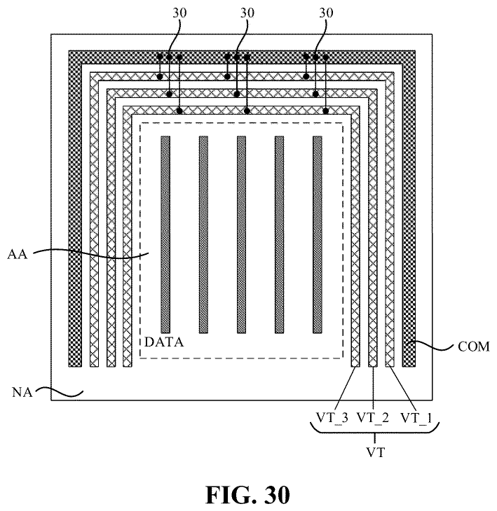

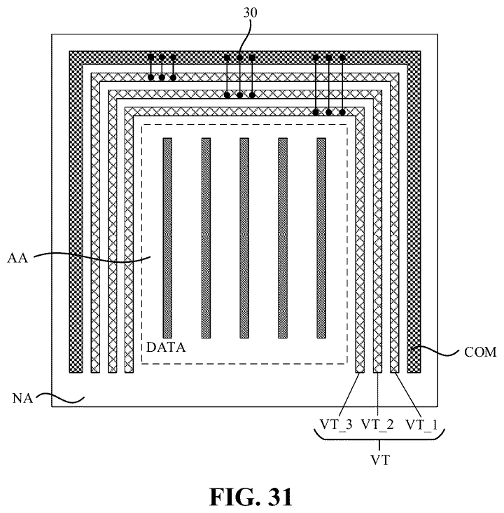

Specifically, the quantity of test signal lines VT is at least two. Exemplarily, three test signal lines VT are taken as an example for the following description. It can be understood that FIG. 28 to FIG. 31 only specifically illustrate the schematic diagram of the position of the electrical connection between each test signal line VT and the common voltage signal line COM, and the actual layout position of the three test signal lines VT may be different from those shown in the figures. Exemplarily, the three test signal lines VT may be located in the same film layer, and the extension directions of respective test signal lines VT are the same and do not overlap each other, or the three test signal lines VT may be located in different film layers, and the test signal lines VT have the overlapping projections on the light-emitting surface of the display panel. Each test signal line VT can be electrically connected to the common voltage signal line COM through at least one connection position 30. Exemplarily, still referring to FIG. 28, each test signal line VT can be electrically connected to the common voltage signal line COM through a first gating circuit SW1 and a connection position 30 in sequence, or each test signal line VT can be electrically connected to the common voltage signal line COM through a connection structure 10 and a connection position 30 in sequence. Still referring to FIG. 29, each test signal line VT can be electrically connected to the common voltage signal line COM through a plurality of corresponding first gating circuits SW1 and a plurality of connection positions 30, or each test signal line VT can be electrically connected to the common voltage signal line COM through a plurality of corresponding connection structures 10 and a plurality of connection positions 30. This embodiment is only for example here but not for the purpose of limitation. Moreover, different test signal lines VT have different connection positions 30 on the common voltage signal line COM, so that different test signal lines VT can detect or compensate for voltage fluctuations of different connection positions 30 on the common voltage signal line COM. Exemplarily, the quantity and position of the connection positions 30 on the common voltage signal line COM can be determined according to the actual size of the display panel and the voltage drop change. It is not necessary for each connection position 30 on the common voltage signal line COM to be electrically connected to the test signal line VT. In this way, the quantity of the first gating circuit SW1 or the connection structure 10 can be effectively reduced, and the space in the border area NA can be further saved, which is conducive to the design of a narrow border. Exemplarily, continuing to refer to FIG. 30, each test signal line VT is electrically connected to the common voltage signal line COM through three connection positions 30, and each test signal line VT can detect or compensate for the voltage fluctuations of different connection positions 30 on the common voltage signal line COM. Continuing to refer to FIG. 31, each test signal line VT is electrically connected to the common voltage signal line COM through three connection positions 30, and different test signal lines VT detect or compensate for the voltage fluctuations of different connection positions 30 on the common voltage signal line COM.

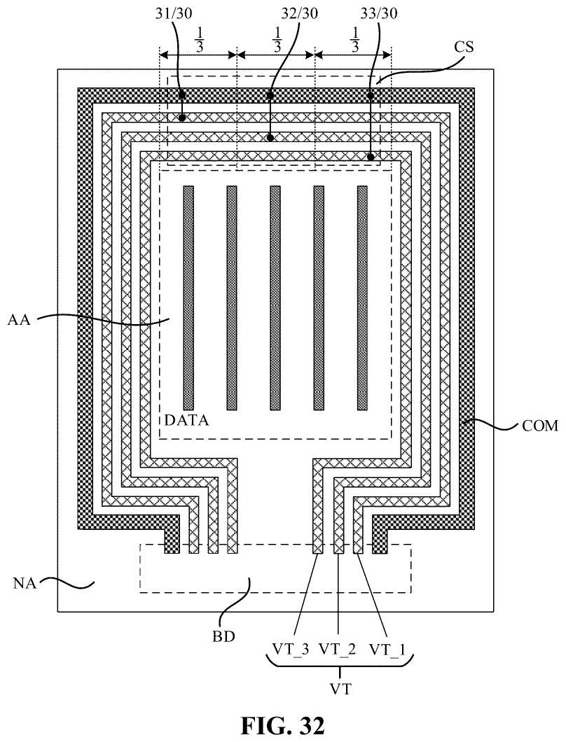

Further, FIG. 32 is a schematic structural diagram of another display panel provided by an embodiment of the present disclosure. As shown in FIG. 32, the test signal line VT includes a first test signal line VT_1, a second test signal line VT_2, and a third test signal line VT_3; the first test signal line VT_1 is electrically connected to the common voltage signal line COM at a first position 31 of the common voltage signal line COM, the second test signal line VT_2 is electrically connected to the common voltage signal line COM at a second position 32 of the common voltage signal line COM, and the third test signal line VT_3 is electrically connected to the common voltage signal line COM at a third position 33 of the common voltage signal line COM; the border area NA includes a binding area BD and a test area CS; the binding area BD is used to bind external components, and the test area CS and the binding area BD are located on two sides of the display area AA that are away from each other respectively; the common voltage signal line COM extends in the test area CS, and in the extension direction of the common voltage signal line COM, the first position 31, the second position 32, and the third position 33 are located in different three equal-division areas of the test area CS respectively.

Specifically, the test signal line VT includes a first test signal line VT_1, a second test signal line VT_2, and a third test signal line VT_3. Correspondingly, the connection position 30 includes a first position 31, a second position 32 and a third position 33. Exemplarily, the first test signal line VT_1 can be electrically connected to the first test signal line VT_1 and the common voltage signal line COM at the first position 31 of the common voltage signal line COM through the first gating circuit SW1 or the connection structure 10. The second test signal line VT_2 can be electrically connected to the second test signal line VT_2 and the common voltage signal line COM at the second position 32 of the common voltage signal line COM through the first gating circuit SW1 or the connection structure 10. The third test signal line VT_3 can be electrically connected to the third test signal line VT_3 and the common voltage signal line COM at the third position 33 of the common voltage signal line COM through the first gating circuit SW1 or the connection structure 10. That is, each test signal line VT is electrically connected to the common voltage signal line COM through a connection position 30, and different test signal lines VT have different connection positions 30 on the common voltage signal line COM.

The border area NA includes a binding area BD and a test area CS, and the test area CS and the binding area BD are respectively located on two sides of the display area AA that are away from each other. Exemplarily, in one embodiment, the binding area BD can be located in a lower border area of the display panel, and the test area CS can be located in an upper border area of the display panel. The binding area BD is used to bind external components, exemplarily, the external components can be chips, flexible circuit boards, etc. The test area CS is used to lay out signal lines and electronic components required for VT testing. The common voltage signal line COM extends in the test area CS, and in the extension direction of the common voltage signal line COM, the first position 31, the second position 32 and the third position 33 are respectively located in different three equal-division areas of the test area CS. Exemplarily, taking an extension direction of the common voltage signal line COM parallel to a direction from the left border area to the right border area of the display panel as an example, the test area CS is evenly divided into three areas, the first position 31 can be located in the three equal-division areas close to the left border area of the display panel, the second position 32 can be located in the three equal-division areas close to the middle area of the display panel, and the third position 33 can be located in the three equal-division areas close to the right border area of the display panel. In this way, the first test signal line VT_1 can compensate or detect the common voltage signal corresponding to the first position 31, that is, the first test signal line VT_2 can compensate or detect the corresponding common voltage signal in the three equal-division areas closed to the left border area of the display panel; the second test signal line VT_2 can compensate or detect the common voltage signal corresponding to the second position 32, that is, the second test signal line VT_2 can compensate or detect the corresponding common voltage signal in the three equal-division areas closed to the middle area of the display panel; the third test signal line VT_3 can compensate or detect the common voltage signal corresponding to the third position 33, that is, the third test signal line VT_3 can compensate or detect the corresponding common voltage signal in the three equal-division areas closed to the right border area of the display panel. In addition, of course, it can be understood that the quantity of connection positions 30 on the common voltage signal line COM can also be other numbers, and the position of the connection position 30 on the common voltage signal line COM can also be evenly divided or divided in an otherwise manner according to the actual space for the test area CS.

Optionally, referring to FIG. 2, during the use stage of the display panel, the common voltage signal line COM is configured to be input with the third common voltage signal, where the first common voltage signal V1 and the third common voltage signal V3 are fixed voltage signals, and satisfy V1≥V3, or, during the use stage of the display panel, the common voltage signal line COM is configured to be input with the third common voltage signal according to the second common voltage, where the second common voltage signal V2 and the third common voltage signal V3 are dynamic voltage signals and are negatively correlated.

Specifically, during the use stage of the display panel, the test signal line VT is electrically connected to the common voltage signal line COM. The common voltage signal line COM is configured to be input with the third common voltage signal V3 thereto, and the third common voltage signal V3 is a fixed voltage signal. It can be understood that in the extension direction of the common voltage signal line COM, the voltage signal in the common voltage signal line COM may gradually attenuate, and the voltage signal in the common voltage signal line COM may gradually decrease. Afterwards, the test signal line VT is configured to be input with the first common voltage signal V1, and the first common voltage signal V1 is a fixed voltage signal. It can be understood that since the test signal line VT is not connected to other structures, the attenuation of the voltage signal in the test signal line VT is relatively weak. Therefore, when V1>V3, a relatively high voltage signal can be input into the test signal line VT, so as to compensate for the voltage signal in the common voltage signal line COM, thereby balancing the voltage drop magnitudes at different positions on the common voltage signal line COM. When V1=V3, it can be understood that the test signal line VT is connected in parallel with the common voltage signal line COM, and the test signal line VT also helps to improve the voltage drop amplitude of the voltage signal in the common voltage signal line COM to a certain extent, avoiding the problem of excessive difference in voltage drops at different positions on the common voltage signal line COM, which helps to achieve the display uniformity of the display panel.

Alternatively, during the use stage of the display panel, the test signal line VT is electrically connected to the common voltage signal line COM. The test signal line VT is configured to output the second common voltage signal V2 on the common voltage signal line COM, and the second common voltage signal V2 is a dynamic voltage signal, that is, the test signal line VT can play a role in real-time detection of the voltage fluctuation on the common voltage signal line COM, so as to obtain the voltage magnitudes of the common voltage signal line COM at different extension positions, thereby facilitating the subsequent feedback adjustment of the voltage magnitude input to the common voltage signal line COM. The common voltage signal line COM is configured to be input with the third common voltage signal V3 according to the second common voltage signal V2, and the third common voltage signal V3 is a dynamic voltage signal, that is, the magnitude of the second common voltage signal V2 detected by the test signal line VT can be used to feedback and adjust the magnitude of the third common voltage signal V3 input into the common voltage signal line COM. That is, the second common voltage signal V2 and the third common voltage signal V3 are negatively correlated. Exemplarily, the larger the second common voltage signal V2 is, the smaller the third common voltage signal V3 is, and the smaller the second common voltage signal V2 is, the larger the third common voltage signal V3 is, so as to balance the voltage drop magnitudes at different positions on the common voltage signal line COM.

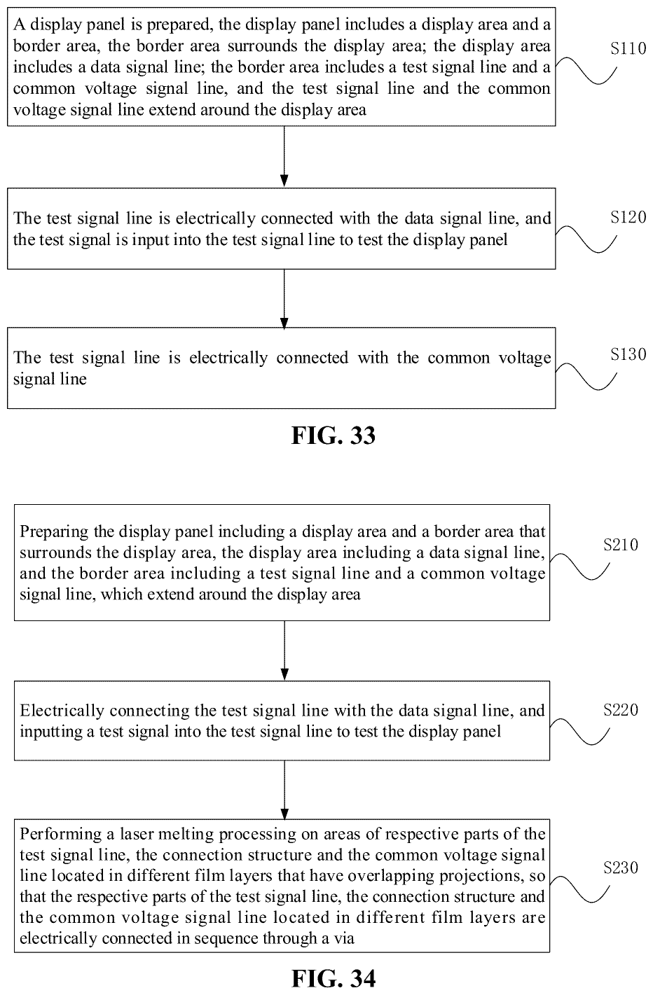

Based on the same inventive concept, an embodiment of the present disclosure also provides a method for preparing a display panel. FIG. 33 is a flowchart of a method for preparing a display panel provided by an embodiment of the present disclosure, and the method for preparing the display panel can be used to prepare the display panels provided by the above-mentioned embodiments of the present disclosure. As shown in FIG. 33, the preparation method includes S110, S120, and S130.

In S110, a display panel is prepared, the display panel includes a display area and a border area, the border area surrounds the display area; the display area includes a data signal line; the border area includes a test signal line and a common voltage signal line, and the test signal line and the common voltage signal line extend around the display area.

Specifically, referring to FIG. 2, the display panel includes a display area AA and a border area NA surrounding the display area AA, where the display area AA includes a data signal line DATA, the border area NA includes a test signal line VT and a common voltage signal line COM, and the test signal line VT and the common voltage signal line COM extend around the display area AA. In this embodiment, the electrical connection between the test signal line VT and the data signal line DATA and the common voltage signal line COM can be reasonably arranged, so that the test signal line VT can be applied to both the test stage of the display panel and the use stage of the display panel.

In S120, the test signal line is electrically connected with the data signal line, and the test signal is input into the test signal line to test the display panel.

Specifically, referring to FIG. 2, in the test stage of the display panel, the test signal line VT can be electrically connected with the data signal line DATA, and the test signal can be input into the test signal line VT, and then transmitted to the data signal line DATA. The data signal line DATA can transmit the test signal to the sub-pixels of multiple colors in the display area AA each, so as to test the display/lighting of the sub-pixels in the display area AA.

In S130, the test signal line is electrically connected with the common voltage signal line.

Specifically, referring to FIG. 2, in the use stage of the display panel, the test signal line VT can be electrically connected with the common voltage signal line COM, and the test signal line VT can be regarded as a part of the common voltage signal line COM, and the test signal line VT plays a role in replacing part of the common voltage signal line COM. Exemplarily, the test signal line VT and the common voltage signal line COM extend around the display area AA, and the electrical connection between the test signal line VT and the common voltage signal line COM can also be understood as the test signal line VT and the common voltage signal line COM being connected in parallel, and the impedance of the common voltage signal line COM can also be further reduced, which is beneficial to improving the stability of the common voltage signal transmitted on the common voltage signal line COM.

In the technical solution in the embodiment of the present disclosure, a display panel is prepared firstly, the display panel includes a display area and a border area, the border area surrounds the display area; the display area includes a data signal line; the border area includes a test signal line and a common voltage signal line, the test signal line and the common voltage signal line extend around the display area, and then the test signal line is electrically connected to the data signal line, and a test signal is input into the test signal line to test the display panel, and finally the test signal line is electrically connected to the common voltage signal line. By using the above-mentioned method, the electrical connection between the test signal line and the data signal line and the common voltage signal line is reasonably arranged, so that the test signal line can be used in both the test stage and the use stage, which improves the situation that the test signal line is useless and idle after the VT test, improves the utilization rate of the test signal line, improves the uniformity and stability of the common voltage signal line, and can effectively reduce the space for the border area of the display panel simultaneously, which is conducive to the narrow border design of the display panel.

FIG. 34 is a flowchart of another method for preparing a display panel provided by an embodiment of the present disclosure, and this embodiment is optimized on the basis of the above-mentioned embodiments. Optionally, the border area also includes a connection structure, and the test signal line, the connection structure and the common voltage signal line span different film layers, one end of the connection structure is electrically connected to the test signal line, and the other end is electrically connected to the common voltage signal line; respective parts of the test signal line, the connection structure and the common voltage signal line located in different film layers have the overlapping projections and are insulated;

The electrically connecting the test signal line with the common voltage signal line includes:

performing a laser melting processing on overlapping areas of projections of the respective parts of the test signal line, the connection structure and the common voltage signal line located in different film layers, so that the respective parts of the test signal line, the connection structure and the common voltage signal line located in different film layers are electrically connected in sequence through vias.

For the contents not yet fully described in this embodiment, please refer to the above-mentioned embodiments. As shown in FIG. 34, the preparation method includes:
S210 preparing the display panel including a display area and a border area that surrounds the display area, the display area including a data signal line, and the border area including a test signal line and a common voltage signal line, which extend around the display area;
S220 electrically connecting the test signal line with the data signal line, and inputting a test signal into the test signal line to test the display panel; and
S230 performing a laser melting processing on areas of respective parts of the test signal line, the connection structure and the common voltage signal line located in different film layers that have overlapping projections, so that the respective parts of the test signal line, the connection structure and the common voltage signal line located in different film layers are electrically connected in sequence through a via.

Specifically, still referring to FIG. 15 and FIG. 16, the border area NA further includes a connection structure 10. The test signal line VT, the connection structure 10 and the common voltage signal line COM span different film layers; one end of the connection structure 10 is electrically connected to the test signal line VT, and the other end is electrically connected to the common voltage signal line COM. Exemplarily, the test signal line VT and the common voltage signal line COM are located in the same film layer, and the connection structure 10 can span the film layer in a direction perpendicular to the light-emitting surface of the display panel to achieve an electrical connection between the test signal line VT and the common voltage signal line COM. During the test stage of the display panel, the respective parts of the test signal line VT, the connection structure 10 and the common voltage signal line COM located in different film layers have the overlapping projections and are insulated. In this way, the test signal line VT is insulated from the common voltage signal line COM, and the test signal line VT can play a role in VT testing, avoiding the influence of the common voltage signal line COM during the VT testing process. Furthermore, since the respective parts of the test signal line VT, the connection structure 10 and the common voltage signal line COM located in different film layers have the overlapping projections, a via 20 can be formed in the area where the projections overlap, and the via 20 spans the film layers to establish an electrical connection relationship between the area where the test signal line VT is located and the area where the common voltage signal line COM is located. During the use stage of the display panel, the respective parts of the test signal line VT, the connection structure 10 and the common voltage signal line COM located in different film layers are electrically connected in sequence through the via 20, so that the test signal line VT is electrically connected to the common voltage signal line COM, and the test signal line VT can play a role in voltage compensation or detection.

Optionally, still referring to FIG. 15 and FIG. 16, the connection structure 10 includes a first connection line 11 and a second connection line 12, and the first connection line 11 and the second connection line 12 are located in different film layers. Here the first end of the first connection line 11 is electrically connected to the common voltage signal line COM, and the first connection line 11 and the common voltage signal line COM can be regarded as a whole. Exemplarily, the first connection line 11 and the common voltage signal line COM can be located in the same film layer, and the first end of the first connection line 11 and the common voltage signal line COM can be electrically connected by contact, or the first connection line 11 and the common voltage signal line COM can be located in different film layers, and the first end of the first connection line 11 and the common voltage signal line COM can be electrically connected through a via 20. This embodiment only exemplarily provides a schematic diagram of the first connection line 11 and the common voltage signal line COM being located in the same film layer. The first end of the second connection line 12 is electrically connected to the test signal line VT, and the second connection line 12 and the test signal line VT can be regarded as a whole. Exemplarily, the second connection line 12 and the test signal line VT can be located in the same film layer, and the first end of the second connection line 12 and the test signal line VT can be electrically connected by contact, or the second connection line 12 and the test signal line VT can be located in different film layers, and the first end of the second connection line 12 and the test signal line VT can be electrically connected through a via 20. This embodiment only exemplarily shows a schematic diagram of the second connection line 12 and the test signal line VT being located in different film layers.

Continuing to refer to FIG. 15 and FIG. 16, in the test stage of the display panel, the second end of the first connection line 11 and the second end of the second connection line 12 overlap in projection on the light-emitting surface of the display panel, and the second end of the first connection line 11 and the second end of the second connection line 12 are insulated, so that the first connection line 11 and the second connection line 12 are insulated, and then the test signal line VT and the common voltage signal line COM are insulated, and the test signal line VT can play a role in VT testing, avoiding the influence of the common voltage signal line COM during the VT testing process. In addition, since the second end of the first connection line 11 and the second end of the second connection line 12 overlap in projection on the light-emitting surface of the display panel, a via 20 can be formed in the area where the projection overlaps, and the via 20 spans the film layer, and establishes an electrical connection relationship between the film layer where the first connection line 11 is located and the film layer where the second connection line 12 is located, and then establishes an electrical connection relationship between the area where the test signal line VT is located and the area where the common voltage signal line COM is located. Continuing to refer to FIG. 17 and FIG. 18, during the use stage of the display panel, the second end of the first connection line 11 and the second end of the second connection line 12 are electrically connected through the via 20, so that the common voltage signal line COM is electrically connected to the test signal line VT through the first connection line 11, the via 20, and the second connection line 12 in sequence, and the test signal line VT can play a role in voltage compensation or detection.

Optionally, still referring to FIG. 23 and FIG. 24, the connection structure 10 includes a first connection line 11, a second connection line 12, a first bonding pad 13 and a second bonding pad 14, the first connection line 11 and the first bonding pad 13 are in the same layer, the second connection line 12 and the second bonding pad 14 are in the same layer, and the first connection line 11 and the second connection line 12 are in different film layers. Here the first end of the first connection line 11 is electrically connected to the common voltage signal line COM, and the second end of the first connection line 11 is electrically connected to the first bonding pad 13. The common voltage signal line COM, the first connection line 11 and the first bonding pad 13 can be regarded as a whole. Exemplarily, the first connection line 11 and the common voltage signal line COM can be located in the same film layer, and the first end of the first connection line 11 and the common voltage signal line COM can be electrically connected by contact. Alternatively, the first connection line 11 and the common voltage signal line COM can be located in different film layers, and the first end of the first connection line 11 and the common voltage signal line COM can be electrically connected through a via 20. This embodiment only exemplarily provides a schematic diagram of the first connection line 11 and the common voltage signal line COM being located in the same film layer. The first end of the second connection line 12 is electrically connected to the test signal line VT, and the second end of the second connection line 12 is electrically connected to the second bonding pad 14. The test signal line VT, the second connection line 12 and the second bonding pad 14 can be regarded as a whole. Exemplarily, the second connection line 12 and the test signal line VT can be located in the same film layer, and the first end of the second connection line 12 and the test signal line VT can be electrically connected by contact. Alternatively, the second connection line 12 and the test signal line VT can be located in different film layers, and the first end of the second connection line 12 and the test signal line VT can be electrically connected through a via 20. This embodiment only exemplarily provides a schematic diagram of the second connection line 12 and the test signal line VT being located in different film layers.

Continuing to refer to FIG. 23 and FIG. 24, in the test stage of the display panel, the first bonding pad 13 and the second bonding pad 14 have the overlapping projections on the light-emitting surface of the display panel, and the first bonding pad 13 and the second bonding pad 14 are insulated, so that the first bonding pad 13 and the second bonding pad 14 are insulated, the first connection line 11 and the second connection line 12 are insulated, and then the test signal line VT and the common voltage signal line COM are insulated, and the test signal line VT can play a role in VT testing, avoiding the influence of the common voltage signal line COM during the VT testing process. In addition, since the first bonding pad 13 and the second bonding pad 14 have the overlapping projections on the light-emitting surface of the display panel, a via 20 can be formed in the overlapping area of the projection, and the via 20 spans the film layer, and establishes an electrical connection relationship between the film layer where the first bonding pad 13 is located and the film layer where the second bonding pad 14 is located, that is, establishes an electrical connection relationship between the film layer where the first connection line 11 is located and the film layer where the second connection line 12 is located, and then establishes an electrical connection relationship between the area where the test signal line VT is located and the area where the common voltage signal line COM is located. Continuing to refer to FIG. 25 and FIG. 26, during the use stage of the display panel, the first bonding pad 13 and the second bonding pad 14 are electrically connected through the via 20, so that the common voltage signal line COM is electrically connected to the test signal line VT through the first connection line 11, the first bonding pad 13, the via 20, the second bonding pad 14, and the second connection line 12 in sequence, and the test signal line VT can play a role in voltage compensation or detection.

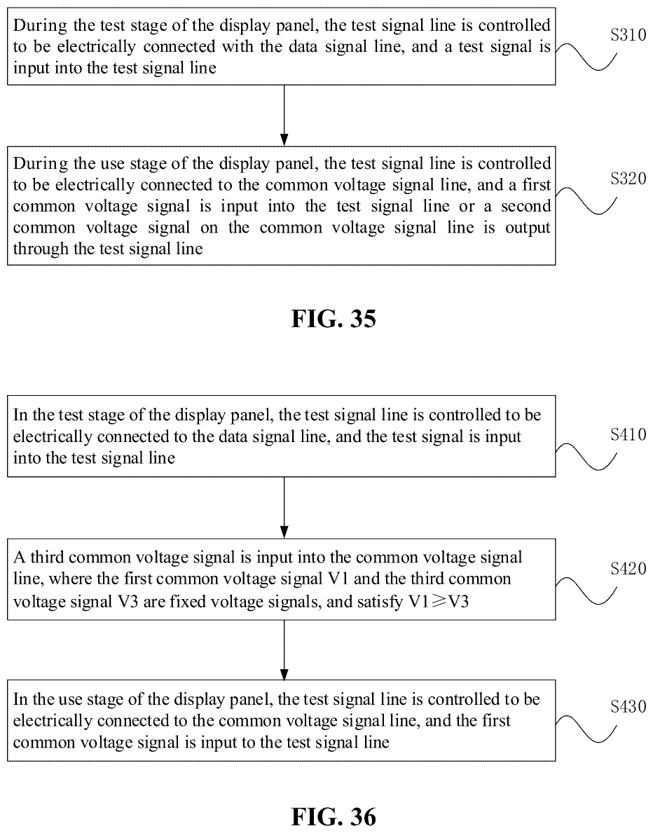

Based on the same inventive concept, an embodiment of the present disclosure also provides a method for using a display panel. FIG. 35 is a flowchart of a method for using a display panel provided by an embodiment of the present disclosure, and the method for using the display panel can be used to realize the normal application of the display panel provided by the above-mentioned embodiments of the present disclosure. Still referring to FIG. 2, the display panel includes a display area AA and a border area NA that surrounds the display area AA; the display area AA includes a data signal line DATA; the border area NA includes a test signal line VT and a common voltage signal line COM that extend around the display area AA. As shown in FIG. 35, the use method includes S310 and S320.

In S310, during the test stage of the display panel, the test signal line is controlled to be electrically connected with the data signal line, and a test signal is input into the test signal line.

Specifically, referring to FIG. 2, in the test stage of the display panel, the test signal line VT can be controlled to be electrically connected to the data signal line DATA, and a test signal can be input into the test signal line VT, and then transmitted to the data signal line DATA. The data signal line DATA can transmit the test signal to the sub-pixels of multiple colors in the display area AA each, so as to carry out the display/lighting test of the sub-pixels in the display area AA.

In S320, in the use stage of the display panel, the test signal line is controlled to be electrically connected to the common voltage signal line, and a first common voltage signal is input into the test signal line or a second common voltage signal on the common voltage signal line is output through the test signal line.

Specifically, still referring to FIG. 2, in the use stage of the display panel, the test signal line VT can be controlled to be electrically connected to the common voltage signal line COM, and a first common voltage signal is input into the test signal line VT. Exemplarily, the test signal line VT can play a role in compensating for the voltage drop of the voltage on the common voltage signal line COM, so as to balance the voltage drop magnitudes of the voltages of the common voltage signal line COM at different extension positions, and improve the uniformity and stability of the panel. Exemplarily, the first common voltage signal can change in real time according to the fluctuation of the voltage on the common voltage signal line COM and be input into the test signal line VT. Alternatively, during the use stage of the display panel, the test signal line VT can be controlled to be electrically connected to the common voltage signal line COM, and the second common voltage signal on the common voltage signal line COM can be output via the test signal line VT.

Exemplarily, the test signal line VT can play a role in detecting the fluctuation of the voltage on the common voltage signal line COM to obtain the magnitudes of the voltages of the common voltage signal line COM at different extension positions, so as to facilitate the subsequent feedback adjustment of the magnitude of the voltage input to the common voltage signal line COM. Exemplarily, the second common voltage signal can obtain the voltage on the common voltage signal line COM in real time according to the refresh frequency of the panel and output the voltage.

According to the technical solutions of the embodiments of the present disclosure, first, in the test stage of the display panel, the test signal line is controlled to be electrically connected with the data signal line, and a test signal is input into the test signal line; then, in the use stage of the display panel, the test signal line is controlled to be electrically connected with the common voltage signal line, and a first common voltage signal is input into the test signal line or a second common voltage signal on the common voltage signal line is output through the test signal line. By using the above scheme, the electrical connection relationships of the test signal line with the data signal line and the common voltage signal line are reasonably set, so in the test stage of the display panel, the test signal is input into the test signal line and transmitted to the data signal line, so as to realize the VT test of the display panel, and in the use stage of the display panel, the common voltage signal can be input into the test signal line or the test signal line can output the common voltage signal and balance the voltage drop of the common voltage signal line in the extension direction. In this way, the test signal line can be used in both the test stage and the use stage, which improves the situation that the test signal line is useless and idle after the VT test, improves the utilization rate of the test signal line with no need to arrange an additional detection signal line to monitor the voltage fluctuation on the common voltage signal line, improves the uniformity and stability of the common voltage signal line, and can effectively reduce the space for the border area of the display panel to facilitate realization of the narrow border design of the display panel.

FIG. 36 is a flowchart of another method for preparing a display panel provided by an embodiment of the present disclosure, and this embodiment is optimized on the basis of the above-mentioned embodiments. Optionally, the controlling the test signal line to be electrically connected to the common voltage signal line, and inputting a first common voltage signal into the test signal line or outputting a second common voltage signal on the common voltage signal line through the test signal line includes:
controlling the test signal line to be electrically connected to the common voltage signal line, and inputting a first common voltage signal to the test signal line;
prior to the controlling the test signal line to be electrically connected to the common voltage signal line, and inputting a first common voltage signal into the test signal line, the method further includes:
inputting a third common voltage signal to the common voltage signal line, where the first common voltage signal V1 and the third common voltage signal V3 are fixed voltage signals, and satisfy V1≥V3.

Please refer to the above-mentioned embodiments for the contents that are not yet detailed in this embodiment. As shown in FIG. 36, the use method includes S410, S420, and S430.

In S410, in the test stage of the display panel, the test signal line is controlled to be electrically connected to the data signal line, and the test signal is input into the test signal line.

In S420, a third common voltage signal is input into the common voltage signal line, where the first common voltage signal V1 and the third common voltage signal V3 are fixed voltage signals, and satisfy V1≥V3.

Specifically, continuing to refer to FIG. 2, in the use stage of the display panel, the test signal line VT can be electrically connected to the common voltage signal line COM, and the third common voltage signal V3 is input into the common voltage signal line COM, and the third common voltage signal V3 is a fixed voltage signal. It can be understood that in the extension direction of the common voltage signal line COM, the voltage signal in the common voltage signal line COM may gradually attenuate, and the voltage signal in the common voltage signal line COM may gradually decrease.

In S430, in the use stage of the display panel, the test signal line is controlled to be electrically connected to the common voltage signal line, and the first common voltage signal is input to the test signal line.

Specifically, referring to FIG. 2, after the third common voltage signal V3 is input into the common voltage signal line COM, the first common voltage signal V1 is input into the test signal line VT, and the first common voltage signal V1 is a fixed voltage signal. It can be understood that since the test signal line VT is not connected to other structures, the attenuation of the voltage signal in the test signal line VT is relatively weak. Therefore, when V1>V3, a relatively high voltage signal can be input into the test signal line VT to compensate for the voltage signal in the common voltage signal line COM, so as to balance the voltage drop magnitudes of the voltages at different positions on the common voltage signal line COM; and when V1=V3, it can be understood that the test signal line VT is connected in parallel with the common voltage signal line COM, and the test signal line VT also helps to improve the voltage drop amplitude of the voltage signal in the common voltage signal line COM to a certain extent, avoids the problem of excessive difference in voltage drops at different positions on the common voltage signal line COM, and helps to achieve the display uniformity of the display panel.

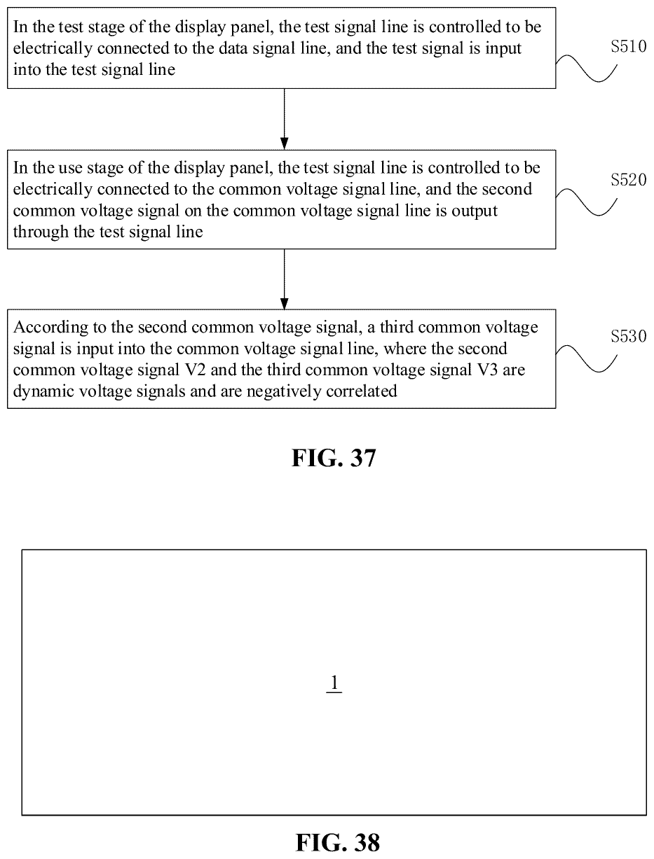

FIG. 37 is a flowchart of another method for preparing a display panel provided in an embodiment of the present disclosure, and this embodiment is optimized on the basis of the above-mentioned embodiments. Optionally, the controlling the test signal line to be electrically connected to the common voltage signal line, and inputting a first common voltage signal into the test signal line or outputting a second common voltage signal on the common voltage signal line through the test signal line includes:

controlling the test signal line to be electrically connected to the common voltage signal line, and outputting the second common voltage signal on the common voltage signal line through the test signal line;

after controlling the test signal line to be electrically connected to the common voltage signal line, and outputting the second common voltage signal on the common voltage signal line through the test signal line, the method further includes:

inputting a third common voltage signal to the common voltage signal line according to the second common voltage signal, where the second common voltage signal V2 and the third common voltage signal V3 are dynamic voltage signals and are negatively correlated.

Please refer to the above-mentioned embodiments for the contents that are not yet detailed in this embodiment. As shown in FIG. 37, the use method includes S510, S520, and S530.

In S510, in the test stage of the display panel, the test signal line is controlled to be electrically connected to the data signal line, and the test signal is input into the test signal line.

In S520, in the use stage of the display panel, the test signal line is controlled to be electrically connected to the common voltage signal line, and the second common voltage signal on the common voltage signal line is output through the test signal line.

Specifically, referring to FIG. 2, during the use stage of the display panel, the test signal line VT can be controlled to be electrically connected to the common voltage signal line COM. The second common voltage signal V2 on the common voltage signal line COM can be output via the test signal line VT, and the second common voltage signal V2 is a dynamic voltage signal, that is, the test signal line VT can play a role in real-time detection of the voltage fluctuation on the common voltage signal line COM, so as to obtain the magnitudes of the voltages of the common voltage signal line COM at different extension positions, thereby facilitating the subsequent feedback adjustment of the magnitude of the voltage input to the common voltage signal line COM.

In S530, according to the second common voltage signal, a third common voltage signal is input into the common voltage signal line, where the second common voltage signal V2 and the third common voltage signal V3 are dynamic voltage signals and are negatively correlated.

Specifically, still referring to FIG. 2, according to the magnitude of the second common voltage signal V2 detected by the test signal line VT, the magnitude of the third common voltage signal V3 input into the common voltage signal line COM can be feedback and adjusted, and the third common voltage signal V3 is a dynamic voltage signal. That is, the second common voltage signal V2 and the third common voltage signal V3 are negatively correlated. Exemplarily, the larger the second common voltage signal V2 is, the smaller the third common voltage signal V3 is, and the smaller the second common voltage signal V2 is, the larger the third common voltage signal V3 is, so as to balance the voltage drop magnitudes of the voltages at different positions on the common voltage signal line COM.

Based on the same inventive concept, an embodiment of the present disclosure also provides a display device. FIG. 38 is a schematic structural diagram of a display device provided by an embodiment of the present disclosure. As shown in FIG. 38, the display device includes a display panel 1 provided by any one of the embodiments of the present disclosure. Therefore, the display device provided by the embodiment of the present disclosure has the corresponding beneficial effects of the display panel 1 provided by the embodiment of the present disclosure, which will not be repeated here. Exemplarily, the display panel 1 can be a liquid crystal display (LCD) display panel, an organic light emitting diode (OLED) display panel, a micro light emitting diode (Micro-LED) display panel, a mini light emitting diode (Mini-LED) display panel, etc. Exemplarily, the display device can be an electronic device such as a mobile phone, a computer, a smart wearable device (for example, a smart watch), and a vehicle-mounted display device, which is not limited by the embodiment of the present disclosure.

Note that the above are only preferred embodiments of the present disclosure and the technical principles used. Those skilled in the art will understand that the present disclosure is not limited to the specific embodiments described here, and that various obvious changes, readjustments, combinations and substitutions can be made by those skilled in the art without departing from the scope of protection of the present disclosure. Therefore, although the present disclosure has been described in detail through the above embodiments, the present disclosure is not limited to the above embodiments, and may include more other equivalent embodiments without departing from the concept of the present disclosure. The scope of the present disclosure is determined by the scope of the attached claims.

What is claimed is:

1. A display panel, comprising a display area and a border area that surrounds the display area, wherein
the display area comprises a data signal line, and the border area comprises a test signal line and a common voltage signal line, which extend around the display area; and
the test signal line is configured to:
be electrically connected to the data signal line and be input with a test signal during a test stage of the display panel; and
be electrically connected to the common voltage signal line and be input with a first common voltage signal or output a second common voltage signal on the common voltage signal line during a use stage of the display panel.

2. The display panel according to claim 1, wherein the common voltage signal line comprises a first common voltage signal line and a second common voltage signal line, the first common voltage signal line and the second common voltage signal line being connected in parallel;
the first common voltage signal line is located on a side of the test signal line close to the display area, and the second common voltage signal line is located on a side of the test signal line away from the display area; and
the test signal line is configured to:
be electrically connected to the first common voltage signal line and/or the second common voltage signal line during the use stage of the display panel.

3. The display panel according to claim 1, wherein the border area further comprises a first gating circuit and a first control signal line, the first gating circuit being electrically connected to the first control signal line, the test signal line and the common voltage signal line each; and
the first control signal line and the first gating circuit are configured so that:
during the test stage of the display panel, the first control signal line receives an inactive level signal, and the first gating circuit controls the test signal line and the common voltage signal line to be disconnected according to the inactive level signal; and
during the use stage of the display panel, the first control signal line receives an active level signal, and the first gating circuit controls the test signal line and the common voltage signal line to be connected according to the active level signal.

4. The display panel according to claim 3, wherein the first gating circuit comprises a plurality of first gating units, each of which comprises a first end, a second end and a first control end, and the first gating unit is an N-type channel transistor or a P-type channel transistor;
the test signal line comprises a first test signal line, a second test signal line and a third test signal line;
the first test signal line, the second test signal line and the third test signal line are electrically connected to first ends of the first gating units that are different respectively, and second ends of the first gating units are electrically connected to the common voltage signal line;
the first control ends of the first gating units that are different are connected to the first control signal lines that are different, or the first control ends of the first gating units that are different are connected to the same first control signal line;
or,
the first gating circuit comprises a first gating unit comprising a first end, a second end and a first control end;
the test signal line comprises a first test signal line, a second test signal line and a third test signal line;
the first test signal line, the second test signal line and the third test signal line are electrically connected to the first end of the first gating unit, the second end of the first gating unit is electrically connected to the common voltage signal line, and the first control end of the first gating unit is electrically connected to the first control signal line.

5. The display panel according to claim 3, wherein the border area further comprises a second gating circuit and a second control signal line, the second gating circuit being electrically connected to the second control signal line, the test signal line and the data signal line each; and
wherein the second control signal line and the second gating circuit are configured so that:
during the test stage of the display panel, the second control signal line receives an active level signal, and the second gating circuit controls the test signal line and the data signal line to be connected according to the active level signal; and
during the use stage of the display panel, the second control signal line receives an inactive level signal, and the second gating circuit controls the test signal line and the data signal line to be disconnected according to the inactive level signal.

6. The display panel according to claim 5, wherein the second gating circuit comprises a plurality of second gating units, each of which comprises a third end, a fourth end and a second control end;
the data signal line comprises a first data signal line, a second data signal line and a third data signal line; the test signal line comprises a first test signal line, a second test signal line and a third test signal line;
the first test signal line and the first data signal line are connected to a third end and a fourth end of one of the second gating units respectively; the second test signal line and the second data signal line are connected to the third end and the fourth end of one of the second gating units respectively; the third test signal line and the third data signal line are connected to the third end and the fourth end of one of the second gating units respectively; and
the second control ends of the second gating units that are different are connected to the second control signal lines that are different, or the second control ends of the second gating units that are different are connected to the same second control signal line.

7. The display panel according to claim 5, wherein the second control signal line also serves as the first control signal line, and the second control signal line is electrically connected to the first gating circuit; and
wherein the second control signal line, the first gating circuit and the second gating circuit are configured so that:
during the test stage of the display panel, the second control signal line receives a first level signal as an inactive level signal of the first gating circuit and an active level signal of the second gating circuit, the first gating circuit controls the test signal line and the common voltage signal line to be disconnected according to the first level signal, and the second gating circuit controls the test signal line and the data signal line to be connected according to the first level signal; and
during the use stage of the display panel, the second control signal line receives a second level signal as an active level signal of the first gating circuit and an inactive level signal of the second gating circuit, the first gating circuit controls the test signal line and the common voltage signal line to be connected according to the second level signal, and the second gating circuit controls the test signal line and the data signal line to be disconnected according to the second level signal.

8. The display panel according to claim 1, wherein the border area further comprises a connection structure; the test signal line, the connection structure and the common voltage signal line span different film layers; one end of the connection structure is electrically connected to the test signal line, and other end is electrically connected to the common voltage signal line; and
during the test stage of the display panel, respective parts of the test signal line, the connection structure and the common voltage signal line located in different film layers have overlapping projections and are insulated;
during the use stage of the display panel, the respective parts of the test signal line, the connection structure and the common voltage signal line located in different film layers are electrically connected in sequence through a via.

9. The display panel according to claim 8, wherein the connection structure comprises a first connection line and a second connection line that are located in different film layers, a first end of the first connection line being electrically connected to the common voltage signal line, and a first end of the second connection line being electrically connected to the test signal line, and a second end of the first connection line and a second end of the second connection line having overlapping projections on a light-emitting surface of the display panel; and
during the test stage of the display panel, the second end of the first connection line and the second end of the second connection line are insulated;
during the use stage of the display panel, the second end of the first connection line and the second end of the second connection line are electrically connected through a via.

10. The display panel according to claim 8, wherein the connection structure comprises a first connection line, a second connection line, a first bonding pad and a second bonding pad, the first connection line and the first bonding pad being in a same layer, the second connection line and the second bonding pad being in a same layer, and the first connection line and the second connection line being in different film layers;
a first end of the first connection line is electrically connected to the common voltage signal line, and a second end of the first connection line is electrically connected to the first bonding pad; a first end of the second connection line is electrically connected to the test signal line, and a second end of the second connection line is electrically connected to the second bonding pad; the first bonding pad and the second bonding pad have overlapping projections on a light-emitting surface of the display panel; and
during the test stage of the display panel, the first bonding pad and the second bonding pad are insulated;
during the use stage of the display panel, the first bonding pad and the second bonding pad are electrically connected through a via.

11. The display panel according to claim 8, wherein the border area further comprises a second gating circuit and a second control signal line, the second gating circuit being electrically connected to the second control signal line, the test signal line and the data signal line each; and
wherein the second control signal line and the second gating circuit are configured so that:
during the test stage of the display panel, the second control signal line receives an active level signal, and the second gating circuit controls the test signal line and the data signal line to be connected according to the active level signal; and
during the use stage of the display panel, the second control signal line receives an inactive level signal, and the second gating circuit controls the test signal line and the data signal line to be disconnected according to the inactive level signal.

12. The display panel according to claim 1, wherein a quantity of the test signal lines is at least two; and
each of the test signal lines is electrically connected to the common voltage signal line through at least one connection position, and the test signal lines that are different have different connection positions on the common voltage signal line.

13. The display panel according to claim 12, wherein the test signal line comprises a first test signal line, a second test signal line and a third test signal line;
the first test signal line is electrically connected to the common voltage signal line at a first position of the common voltage signal line, the second test signal line is electrically connected to the common voltage signal line at a second position of the common voltage signal line, and the third test signal line is electrically connected to the common voltage signal line at a third position of the common voltage signal line;
the border area comprises a binding area and a test area, the binding area being configured to bind external components, and the test area and the binding area being located on two sides of the display area that are away from each other respectively; and
the common voltage signal line extends in the test area, and in an extension direction of the common voltage signal line, the first position, the second position and the third position are located in different three equal-division areas of the test area respectively.

14. The display panel according to claim 1, wherein during the use stage of the display panel, the common voltage signal line is configured to be input with a third common voltage signal, wherein the first common voltage signal V1 and the third common voltage signal V3 are fixed voltage signals and satisfy V1≥V3; or
during the use stage of the display panel, the common voltage signal line is configured to be input with a third common voltage signal according to the second common voltage, wherein the second common voltage signal V2 and the third common voltage signal V3 are dynamic voltage signals and are negatively correlated.

15. A method for preparing a display panel, comprising:
preparing the display panel including a display area and a border area that surrounds the display area, the display area comprising a data signal line, and the border area comprising a test signal line and a common voltage signal line, which extend around the display area;
electrically connecting the test signal line with the data signal line, and inputting a test signal into the test signal line to test the display panel; and
electrically connecting the test signal line with the common voltage signal line.

16. The method according to claim 15, wherein the border area further comprises a connection structure; the test signal line, the connection structure and the common voltage signal line span different film layers; one end of the connection structure is electrically connected to the test signal line, and other end is electrically connected to the common voltage signal line; and respective parts of the test signal line, the connection structure and the common voltage signal line located in different film layers have overlapping projections and are insulated; and
wherein the electrically connecting the test signal line with the common voltage signal line comprises:
performing a laser melting processing on areas of respective parts of the test signal line, the connection structure and the common voltage signal line located in different film layers that have overlapping projections, so that the respective parts of the test signal line, the connection structure and the common voltage signal line located in different film layers are electrically connected in sequence through a via.

17. A method for using a display panel according to claim 1, comprising:
controlling the test signal line to be electrically connected to the data signal line, and inputting a test signal into the test signal line during a test stage of the display panel;
controlling the test signal line to be electrically connected to the common voltage signal line, and inputting a first common voltage signal into the test signal line or outputting a second common voltage signal on the common voltage signal line through the test signal line during a use stage of the display panel.

18. The method according to claim 17, wherein the controlling the test signal line to be electrically connected to the common voltage signal line, and inputting a first common voltage signal into the test signal line or outputting a second common voltage signal on the common voltage signal line through the test signal line comprises:
controlling the test signal line to be electrically connected to the common voltage signal line, and inputting a first common voltage signal to the test signal line; and
wherein prior to the controlling the test signal line to be electrically connected to the common voltage signal line, and inputting a first common voltage signal into the test signal line, the method further comprises:
inputting a third common voltage signal to the common voltage signal line, wherein the first common voltage signal V1 and the third common voltage signal V3 are fixed voltage signals, and satisfy V1≥V3.

19. The method according to claim 17, wherein the controlling the test signal line to be electrically connected to the common voltage signal line, and inputting a first common voltage signal into the test signal line or outputting a second common voltage signal on the common voltage signal line through the test signal line comprises:
controlling the test signal line to be electrically connected to the common voltage signal line, and outputting the second common voltage signal on the common voltage signal line through the test signal line; and
wherein after controlling the test signal line to be electrically connected to the common voltage signal line, and outputting the second common voltage signal on the common voltage signal line through the test signal line, the method further comprises:
inputting a third common voltage signal to the common voltage signal line according to the second common voltage signal, wherein the second common voltage signal V2 and the third common voltage signal V3 are dynamic voltage signals and are negatively correlated.

20. A display device, comprising a display panel that comprises a display area and a border area surrounding the display area, wherein
the display area comprises a data signal line, and the border area comprises a test signal line and a common voltage signal line, which extend around the display area; and
the test signal line is configured to:
be electrically connected to the data signal line and be input with a test signal during a test stage of the display panel; and
be electrically connected to the common voltage signal line and be input with a first common voltage signal or output a second common voltage signal on the common voltage signal line during a use stage of the display panel.
